(19) United States
(12) Patent Application Publication
(10) Pub. No.: US 2023/0333468 A1
(43) Pub. Date: Oct. 19, 2023

(54) RESIN COMPOSITION, CURED FILM, METHOD FOR MANUFACTURING CURED FILM, SUBSTRATE HAVING MULTILAYER FILM, METHOD FOR PRODUCING PATTERNED SUBSTRATE, PHOTOSENSITIVE RESIN COMPOSITION, METHOD FOR PRODUCING PATTERN CURED FILM, METHOD FOR PRODUCING POLYMER, AND METHOD FOR PRODUCING RESIN COMPOSITION

(71) Applicant: CENTRAL GLASS COMPANY, LIMITED, Ube-shi, Yamaguchi (JP)

(72) Inventors: Takashi MASUBUCHI, Saitama (JP); Yuri OIKAWA, Saitama (JP); Kazuhiro YAMANAKA, Saitama (JP)

(21) Appl. No.: 18/334,125

(22) Filed: Jun. 13, 2023

Related U.S. Application Data
(63) Continuation of application No. PCT/JP2021/046165, filed on Dec. 15, 2021.

(30) Foreign Application Priority Data
Dec. 15, 2020 (JP) 2020-207819

(51) Int. Cl. G03F 7/004; G03F 7/075; G03F 7/09; G03F 7/039; G03F 7/20

(52) U.S. Cl. CPC G03F 7/0043; G03F 7/0757; G03F 7/0048; G03F 7/094; G03F 7/0397; G03F 7/0045; G03F 7/2006; G03F 7/201

(57) ABSTRACT

An object is to provide a resin composition, which is a homogeneous solution containing a polymer, obtained by hydrolysis and polycondensation without precipitation during the sol-gel reaction even when a metal species with high EUV absorbance is introduced. The resin component includes a polymer including a constituent unit represented by (A) a following general formula (1) and (B) a following general formula (1-A),

[(R²)_{d}(R³)ₑ(OR⁴)_{f}SiO_{g/2}] (1)

[(R¹)_{b}MO_{c/2}] (1-A)

In the general formula (1), R² is a group represented by a following general formula (1a).

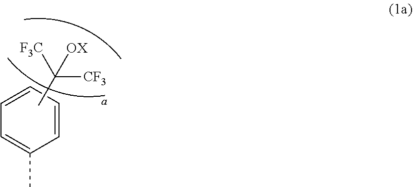

### CROSS-REFERENCE TO RELATED APPLICATIONS

This application is a Continuation of International Patent Application No. PCT/JP2021/046165, filed on Dec. 15, 2021, which claims the benefit of priority to Japanese Patent Application No. 2020-207819, filed on Dec. 15, 2020, the entire contents of which are incorporated herein by reference.

### FIELD

The present disclosure relates to a resin composition, a cured film, a method for manufacturing a cured film, a substrate having multiple layers, a method for producing a substrate having a pattern, a photosensitive resin composition, a method for producing a patterned cured film, a method for producing a polymer, and a method for producing the resin composition.

### BACKGROUND

High integration of LSI (Large Scale Integration) and miniaturization of patterns are advancing. High integration of LSI and miniaturization of patterns have been advanced by shortening of a light source in lithography and developing corresponding resists. Normally, in LSI manufacturing, a pattern forming substrate is manufactured by dry etching the substrate using a chlorine-based gas or a fluorine-based gas and transferring the pattern via a resist pattern formed by exposure and development on the substrate according to lithography. In this case, a resin having a chemical structure that has etching resistance with respect to these gases is used as a resist.

As such a resist, there are a positive resist in which an exposed portion is solubilized by irradiation with light, and a negative resist in which an exposed portion is insolubilized, and either of them is used. In this case, g-line (wavelength 463 nm), i-line (wavelength 365 nm) emitted from a high-pressure mercury lamp, ultraviolet light having a wavelength of 248 nm oscillated by a KrF excimer laser, ultraviolet light having a wavelength of 193 nm oscillated by an ArF excimer laser, or extreme ultraviolet light (hereinafter sometimes referred to as EUV), or the like is used.

On the other hand, a multilayer resist method is known in order to improve the breakdown of a pattern when forming the pattern of the resist and the etching resistance of the resist. In the case where the multilayer resist method is applied to an EUV exposure, the resist layer made of a conventional hydrocarbon has a low absorbance of EUV light, and therefore, for example, Japanese laid-open patent publication No. 2017-224819 and 2018 EUVL Workshop, Workshop Proceedings, p52 disclose that secondary electrons from EUV photons are returned from an underlayer film to the resist side to increase EUV photosensitivity (efficient use of EUV light) by using a material having a high EUV absorbance in the underlayer film of the resist (using an MoSi pair as a multilayer stack).

### SUMMARY

In the case where a metal species with high EUV absorbance is introduced into an underlayer film of a resist, as a method other than using a special self-assembled diblock copolymer described in Japanese laid-open patent publication No. 2017-224819, a simple method is to adopt a sol-gel reaction of alkoxysilane and metal alkoxide other than silicon. However, the present inventors have found that, in a simple sol-gel reaction, a homogeneous solution containing a metal species with high EUV absorbance may not be obtained due to precipitation of components derived from the raw material during the reaction.

Therefore, an object of the present disclosure is to provide a resin composition, which is a homogeneous solution containing a polymer, obtained by hydrolysis and polycondensation without precipitation during the sol-gel reaction even when a metal species with high EUV absorbance is introduced.

In addition, an object of the present disclosure is to provide a resin composition, which is a homogeneous solution containing a mixture, without precipitation in a blend described later even when a metal species with high EUV absorbance is used.

The polymer may be a copolymer obtained by conducting hydrolysis and polycondensation of a metal species monomer with high EUV absorbance and a sol-gel raw material monomer.

The polymer may be a copolymer obtained by conducting hydrolysis and polycondensation of the metal species monomer with high EUV absorbance in advance to oligomerize it, and then conducting hydrolysis and polycondensation of it with the other sol-gel raw material monomers.

The polymer may be a copolymer obtained by conducting hydrolysis and polycondensation of the other sol-gel raw material monomers in advance to oligomerize it and then conducting hydrolysis and polycondensation of it with the metal species monomer with high EUV absorbance.

The polymer may be a copolymer obtained by conducting hydrolysis and polycondensation of the metal species monomer with high EUV absorbance in advance, conducting hydrolysis and polycondensation of the other sol-gel raw material monomers in advance to oligomerize them, and then mixing both oligomers and conducting hydrolysis and polycondensation of them.

The polymer may be a mixture obtained by conducting hydrolysis and polycondensation of the metal species monomer with high EUV absorbance in advance and conducting hydrolysis and polycondensation of the other sol-gel raw material monomers in advance to polymerize them, and then mixing both polymers (hereinafter, sometimes also referred to as “blending”).

In addition, an object of the present disclosure is to provide a cured film obtained by curing a resin composition, or a method for producing the same. Alternatively, an object of the present disclosure is to provide a substrate having multiple layers having an underlayer film of a resist which is a cured film of a resin composition or a method of producing a substrate having a pattern using the substrate having multiple layers.

In addition, an object of the present disclosure is to provide a method for producing a photosensitive resin composition containing a resin composition and a method for producing a patterned cured film formed by coating the photosensitive resin composition on the substrate.

In addition, an object of the present disclosure is to provide a method for producing a polymer obtained by hydrolysis and polycondensation without precipitation during the sol-gel reaction even when a metal species with high EUV absorbance is introduced.

In addition, an object of the present disclosure is to provide a method for producing a resin composition for treating the obtained polymer.

As a result of intensive studies to solve the above problems, the inventors found a resin composition containing a polymer including:
(A) a constituent unit represented by the following general formula (1); and
(B) a constituent unit represented by the following general formula (1-A).

[(R²)_{d}(R³)ₑ(OR⁴)_{f}SiO_{g/2}] (1)

[(R¹)_{b}MO_{c/2}] (1-A)

In the general formula (1-A), M is at least one selected from a group consisting of Fe, Co, Ni, Cu, Zn, Ga, Ge, M o, Pd, Ag, Sn, Cs, Ba, W, and Hf. Each R¹ is independently selected from a group consisting of a hydrogen atom, hydroxyl group, halogen group, an alkoxy group having a carbon number of 1 or more and 5 or less, an alkyl group having a carbon number of 1 or more and 5 or less, a phenyl group, and a fluoroalkyl group having a carbon number of 1 or more and 10 or less.

b is a number of 0 or more and less than 4, c is a number more than 0 and 4 or less, and b+c=3 or 4.

In the general formula (1), R² is a group represented by the following general formula (1a).

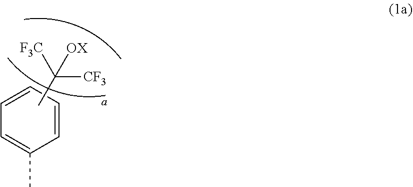

In the general formula (1a), X is a hydrogen atom or an acid-labile group.

a is a number of 1 to 5, and a broken line represents a bond.

each R³ is independently selected from a group consisting of a hydrogen atom, an alkyl group having a carbon number of 1 or more and 5 or less, a phenyl group, and a fluoroalkyl group having a carbon number of 1 or more and 10 or less, and each R⁴ is independently a hydrogen atom or an alkyl group having a carbon number of 1 or more and 5 or less.

d is a number of 1 or more and 3 or less, e is a number of 0 or more and 2 or less, f is a number of 0 or more and less than 3, g is a number more than 0 and 3 or less, and d+e+f+g=4.

In addition, the inventors found a resin composition containing:
(a) a polysiloxane compound including a constituent unit represented by the following general formula (1); and
(b) a metalloxane compound including a constituent unit represented by the following general formula (1-A).

[(R²)_{d}(R³)ₑ(OR⁴)_{f}SiO_{g/2}] (1)

[(R¹)_{b}MO_{c/2}] (1-A)

In the general formula (1-A), M is at least one selected from a group consisting of Fe, Co, Ni, Cu, Zn, Ga, Ge, M o, Pd, Ag, Sn, Cs, Ba, W, and Hf. Each R¹ is independently selected from a group consisting of a hydrogen atom, hydroxyl group, halogen group, an alkoxy group having a carbon number of 1 or more and 5 or less, an alkyl group having a carbon number of 1 or more and 5 or less, a phenyl group, and a fluoroalkyl group having a carbon number of 1 or more and 10 or less.

b is a number of 0 or more and less than 4, c is a number more than 0 and 4 or less, and b+c=3 or 4.

In the general formula (1), R² is a group represented by the following general formula (1a).

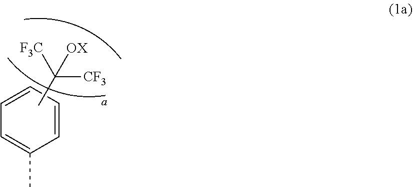

In the general formula (1a), X is a hydrogen atom or an acid-labile group.

a is a number of 1 to 5, and a broken line represents a bond.

Each R³ is independently selected from a group consisting of a hydrogen atom, an alkyl group having a carbon number of 1 or more and 5 or less, a phenyl group, and a fluoroalkyl group having a carbon number of 1 or more and 10 or less, and each R⁴ is independently a hydrogen atom or an alkyl group having a carbon number of 1 or more and 5 or less.

d is a number of 1 or more and 3 or less, e is a number of 0 or more and 2 or less, f is a number of 0 or more and less than 3, g is a number more than 0 and 3 or less, and d+e+f+g=4.

The group represented by the general formula (1a) may be a group represented by any of the following general formulas (1aa) to (1ad).

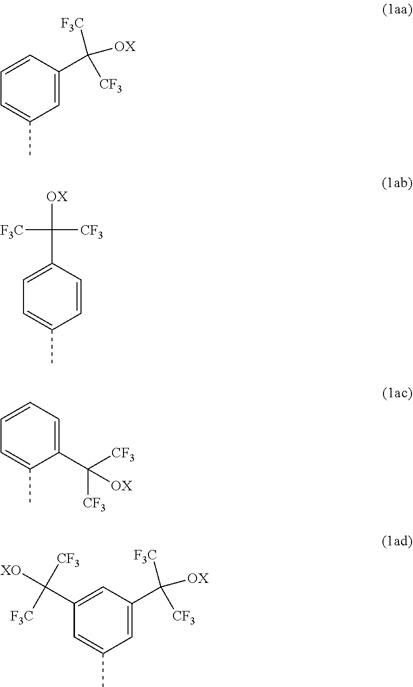

In the general formulas (1aa) to (1ad), the definitions of X and the broken line are the same as the definitions in the general formula (1a).

The polymer as described above or at least one of (a) a polysiloxane compound including a constituent unit represented by the general formula (1) and (b) a metalloxane compound including a constituent unit represented by the general formula (1-A) may further include a constituent unit represented by the following general formula (2) and/or the following general formula (3).

[(R⁵)ₕ(R⁶)ᵢSiO_{j/2}] (2)

[(R⁷)ₖSiO_{l/2}] (3)

In the general formula (2), R⁵ is a substituent selected from monovalent organic groups having a carbon number of 1 or more and 30 or less and substituted by any of an epoxy group, oxetane group, acryloyl group, methacryloyl group, and lactone group.

R⁶ is a hydrogen atom, or a substituent selected from a group consisting of a halogen group, an alkyl group having a carbon number of 1 or more and 5 or less, a phenyl group, hydroxy group, an alkoxy group having a carbon number of 1 or more and 3 or less, and a fluoroalkyl group having a carbon number of 1 or more and 10 or less.

h is a number 1 or more and 3 or less, i is a number of 0 or more and less than 3, j is a number more than 0 and 3 or less, and h+i+j=4.

When there are a plurality of R⁵ and R⁶, each of them is independently selected from any of the substituents.

In the general formula (3), R⁷ is a substituent selected from a group consisting of a halogen group, an alkoxy group, and a hydroxy group.

k is a number of 0 or more and less than 4, l is a number more than 0 and 4 or less, and k+l=4.

The monovalent organic group R⁵ may be any substituent represented by the following general formulas (2a), (2b), (2c), (3a), and (4a).

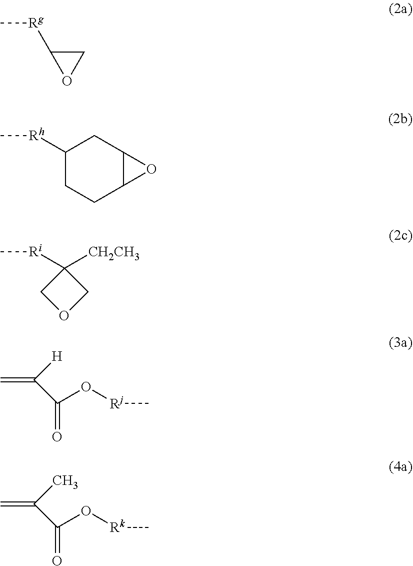

In the general formulas (2a), (2b), and (2c), R^{g}, R^{h}, Rⁱ is independently a divalent linking group, and a broken line represents a bond.

In the general formulas (3a) and (4a), each R^{j} and R^{k} is independently a divalent linking group, and a broken line represents a bond.

In the general formula (1-A), M may be at least one selected from a group consisting of Ge, Mo, and W.

The resin composition may further include:
(C) a solvent.

(C) the solvent may include at least one compound selected from a group consisting of propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols, glycol ethers, and glycol ether esters.

In an embodiment, a cured film obtained by curing the resin composition is provided.

In an embodiment, a method is provided for producing a cured film including a step of applying the resin composition onto a substrate and heating the resin composition at a temperature of 80° C. or more and 350° C. or less.

In an embodiment, a substrate having multiple layers including an organic layer onto a substrate, an underlayer film for a resist, the underlayer film being a cured film wherein the resin composition is cured, and a resist layer on the underlayer film is provided.

In an embodiment, a method is provided of producing a substrate having a pattern including: a first step of exposing the resist layer to the substrate having multiple layers through a photomask to obtain a pattern by developing the exposed resist layer with a developer; a second step of dry etching of the underlayer film through the developed pattern of the resist layer to obtain a pattern of the underlayer film; a third step of dry etching of the organic layer through the pattern of the underlayer film to obtain a pattern of the organic layer; and a fourth step of dry etching of the substrate through the pattern of the organic layer to obtain a pattern of the substrate.

The dry etching of the underlayer film may be performed by a fluorine-based gas in the second step, the dry etching of the organic layer may be performed by an oxygen-based gas in the third step, and the dry etching of the substrate may be performed by a fluorine-based gas or a chlorine-based gas in the fourth step.

A wavelength of the light beam used in the exposure may be 1 nm or more and 600 nm or less.

The wavelength of the light beam used in the exposure may be 6 nm or more and 27 nm or less.

In an embodiment, a photosensitive resin composition is provided including:
the resin composition described above; and
(D) a photoinduced compound.

(D) the photoinduced compound may be at least one selected from a group consisting of naphthoquinonediazide, photoacid generator, photobase generator, and photoradical generator.

In an embodiment, a method is provided for producing a patterned cured film, including: a step of applying the photosensitive resin composition onto a substrate to form a photosensitive application film; exposing the photosensitive application film through a photomask; developing the photosensitive application film after exposure to form a patterned film; and curing the patterned film by heating the patterned film to obtain the patterned cured film.

The photosensitive application film may be exposed by irradiating a light beam having a wavelength 1 nm or more and 600 nm or less through the photomask.

In an embodiment, a method for producing a polymer including: conducting hydrolysis and polycondensation of a silicon compound represented by the following general formula (1y) and a metal compound represented by the following general formula (1-2) is provided.

The produced polymer includes a constituent unit represented by the following general formula (1) and a constituent unit represented by the following general formula (1-A).

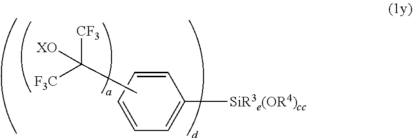

M(R⁸)ₘ(R⁹)ₙ (1-2)

[(R²)_{d}(R³)ₑ(OR⁴)_{f}SiO_{g/2}] (1)

[(R¹)_{b}MO_{c/2}] (1-A)

In the general formula (1y), each R³ is independently selected from a group consisting of a hydrogen atom, an alkyl group having a carbon number of 1 or more and 5 or less, a phenyl group, and a fluoroalkyl group having a carbon number of 1 or more and 10 or less, and each R⁴ is independently a hydrogen atom or an alkyl group having a carbon number of 1 or more and 5 or less. a is a number of 1 to 5, and d is a number of 1 or more and 3 or less. e is a number of 0 or more and 2 or less. cc is a number of 1 or more and less than 4. d+e+cc=4. X is a hydrogen atom or an acid-labile group.

In the general formula (1-2), M is at least one selected from a group consisting of Fe, Co, Ni, Cu, Zn, Ga, Ge, M o, Pd, Ag, Sn, Cs, Ba, W, and Hf. Each R⁸ is independently selected from a group consisting of a hydrogen atom, hydroxy group, an alkyl group having a carbon number of 1 or more and 5 or less, a phenyl group, and a fluoroalkyl group having a carbon number of 1 or more and 10 or less, and R⁹ is an alkoxy group having a carbon number of 1 or more and 5 or less, or a halogen.

m is a number of 0 or more and 3 or less, n is a number of 1 or more and 4 or less, and m+n=3 or 4.

In the general formula (1-A), M is at least one selected from a group consisting of Fe, Co, Ni, Cu, Zn, Ga, Ge, Mo, Pd, Ag, Sn, Cs, Ba, W, and Hf, and each R¹ is independently selected from a group consisting of a hydrogen atom, hydroxyl group, halogen group, an alkoxy group having a carbon number of 1 or more and 5 or less, an alkyl group having a carbon number of 1 or more and 5 or less, a phenyl group, and fluoroalkyl group having a carbon number of 1 or more and 10 or less.

b is a number of 0 or more and less than 4, c is a number more than 0 and 4 or less, and b+c=3 or 4.

In the general formula (1), R² is a group represented by the following general formula (1a).

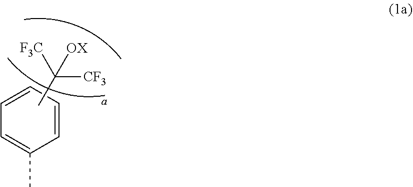

In the general formula (1a), X is a hydrogen atom or an acid-labile group.

a is a number of 1 to 5, and a broken line represents a bond.

Each R³ is independently selected from a group consisting of a hydrogen atom, an alkyl group having a carbon number of 1 or more and 5 or less, a phenyl group, and a fluoroalkyl group having a carbon number of 1 or more and 10 or less, and each R⁴ is independently a hydrogen atom or an alkyl group having a carbon number of 1 or more and 5 or less.

d is a number of 1 or more and 3 or less, e is a number of 0 or more and 2 or less, f is a number of 0 or more and less than 3, g is a number more than 0 and 3 or less, and d+e+f+g=4.

A chelator may be added to the metal compound represented by the general formula (1-2) during the hydrolysis and polycondensation or before the hydrolysis and polycondensation.

In an embodiment, a method is provided for producing the resin composition including: performing at least one operation selected from a group consisting of a dilution, a concentration, an extraction, a water washing, an ion exchange resin purification, and a filtration with respect to the polymer obtained by the method for producing the polymer described above.

### BRIEF DESCRIPTION OF DRAWINGS

FIG. 1 is a schematic diagram illustrating a method of producing a substrate 150 having a pattern according to an embodiment of the present invention FIG. 1.

FIG. 2 is a schematic diagram illustrating a method of producing a patterned cured film 211 according to an embodiment of the present invention.

### DESCRIPTION OF EMBODIMENTS

Hereinafter, a resin composition, a cured film, a method for producing a cured film, a substrate having multiple layers, a method for producing a substrate having a pattern, a photosensitive resin composition, a method for producing a patterned cured film, a method for producing a polymer, and a method for producing a resin composition according to an embodiment of the present invention will be described. However, the embodiments of the present invention are not to be construed as being limited to the descriptions of the embodiments and examples described below. In the present specification, the expression “Xa to Ya” in describing a numerical value range means Xa or more and Ya or less unless otherwise specified.

As a result of intensive studies to solve the above problems, the present inventors have found that when a raw material of a specific constituent unit containing a hexafluoroisopropanol (HFIP) group represented by a general formula (1) to be described later and a raw material of a specific constituent unit represented by a general formula (1-A) to be described later containing a metal species with high EUV absorbance are combined, hydrolysis and polycondensation can be performed while suppressing precipitation of components derived from the raw material in the sol-gel reaction, and as a result, a resin composition which is a homogeneous solution containing a polymer can be obtained.

In addition, the present inventors have found that when a polysiloxane compound obtained by polymerizing a raw material of a specific constituent unit containing a hexafluoroisopropanol (HFIP) group represented by the general formula (1) and metalloxane compound obtained by polymerizing a raw material of a specific constituent unit represented by the general formula (1-A) containing a metal species with high EUV absorbance are combined, precipitation can be suppressed in a blend of the two. As a result, it has been found that a resin composition that is a homogeneous solution containing a mixture can be obtained.

In addition, it has been found that a substrate having multiple layers using the cured film as an underlayer film of a resist has excellent etch selectivity because a cured film uniformly containing a metal species with high EUV absorbance can be obtained by curing the resin composition of the present invention.

In the present specification, “suppress precipitation” refers to a state in which a sediment and/or a precipitate derived from a raw material cannot be visually confirmed in a resin composition or a photosensitive resin composition. In addition, in the present specification, a state in which sedimentation is suppressed may be referred to as “dispersion”.

In the present specification, the term “dispersion” may refer to, for example, a state in which (B) a constituent unit represented by the general formula (1-A) is incorporated into a network through an interaction (for example, a copolymerization reaction or the like) with another component contained in a resin composition or a photosensitive resin composition.

If a precipitate is contained in the resin composition or the photosensitive resin composition, there is concern that the smoothness of the film surface at the time of film formation is impaired. In addition, there is concern that the precipitate contained in the resin composition or the photosensitive resin composition may cause film cracking. Furthermore, fine particles larger than the EUV wavelength may adversely affect EUV exposure. However, these problems in the prior art are solved by the resin composition and the photosensitive resin composition according to the present invention being a homogeneous solution.

In an embodiment, the polymer of the present invention includes a polymer including (A) a constituent unit represented by the general formula (1) and (B) a constituent unit represented by the general formula (1-A).

In addition, the polymer of the present invention includes a polymer including (a) a polysiloxane compound including a constituent unit represented by the general formula (1), and (b) a metalloxane compound including a constituent unit represented by the general formula (1-A).

### [(A) Constituent Unit Represented by General Formula (1)]

(A) is a constituent unit represented by the following general formula (1) (hereinafter also referred to as “first constituent unit”).

In addition, (a) is a polysiloxane compound including a constituent unit represented by the following general formula (1):

[(R²)_{d}(R³)ₑ(OR⁴)_{f}SiO_{g/2}] (1)

In the general formula (1), R² is a group represented by the following general formula (1a).

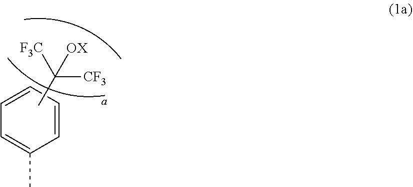

In the general formula (1a), X is a hydrogen atom or an acid-labile group.

a is a number of 1 to 5, and a broken line represents a bond.

Each R³ is independently selected from a group consisting of a hydrogen atom, an alkyl group having a carbon number of 1 or more and 5 or less, a phenyl group, and a fluoroalkyl group having a carbon number of 1 or more and 10 or less, and each R⁴ is independently a hydrogen atom or an alkyl group having a carbon number of 1 or more and 5 or less.

d is a number of 1 or more and 3 or less, e is a number of 0 or more and 2 or less, f is a number of 0 or more and less than 3, g is a number more than 0 and 3 or less, and d+e+f+g=4.

In this case, in the first constituent unit represented by the general formula (1), as theoretical values of d, e, f, and g, d is an integer of 1 to 3, e is an integer of 0 to 2, f is an integer of 0 to 3, and g is an integer of 0 to 3. In addition, d+e+f+g=4 means that the sum of the theoretical values is 4. However, for example, in the value obtained by ²⁹Si NMR measurement, d may be a decimal that would be 1 or more and 3 or less when rounded, e may be a decimal that may be 0 or more and 2 or less when rounded, f may be a decimal that would be 0 or more and 2 or less when rounded (where f<3.0), and g may be a decimal that would be 0 or more and 3 or less when rounded (where g≠0). The description that g is an integer of 0 to 3 as a theoretical value, and g is a decimal that would be 0 or more and 3 or less when rounded (where g≠0) as a value obtained by ²⁹Si NMR measurement indicates that a monomer may be adopted as the first constituent unit, but not all of the constituent units are monomers.

In the monovalent group represented by the general formula (1a), a is an integer of 1 or more and 5 or less as a theoretical value. However, for example, the value obtained by ²⁹Si NMR measurement may be a decimal that would be 1 or more and 5 or less when rounded.

In an embodiment, a group represented by the general formula (1a) may be a group represented by any of the following general formulas (1aa) to (1ad). In the general formulas (1aa) to (1ad), X and the broken line are the same as the definitions in the general formula (1a).

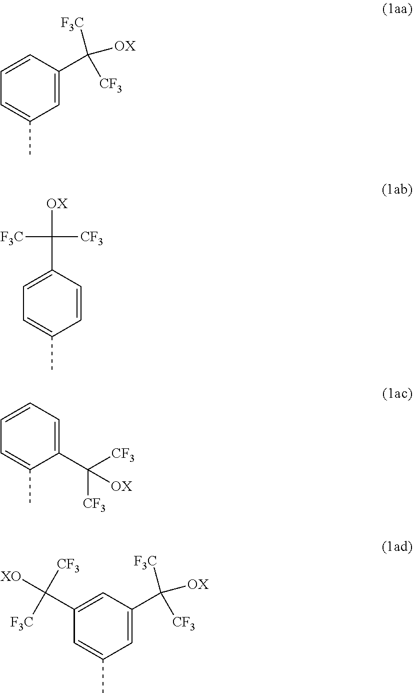

In an embodiment, the polymer in the resin composition of the present invention or at least one of (a) the polysiloxane compound including a constituent unit represented by the general formula (1) and (b) the metalloxane compound including a constituent unit represented by the general formula (1-A) may further include a constituent unit represented by the following general formula (2) (hereinafter also referred to as “second constituent unit”) and/or a constituent unit represented by the following general formula (3) (hereinafter also referred to as “third constituent unit”).

[(R⁵)ₕ(R⁶)ᵢSiO_{j/2}] (2)

[(R⁷)ₖSiO_{l/2}] (3)

In the general formula (2), R⁵ is a substituent selected from monovalent organic groups having a carbon number of 1 or more and 30 or less substituted by any of an epoxy group, oxetane group, acryloyl group, methacryloyl group, and lactone group. R⁶ is a hydrogen atom, or a substituent selected from a group consisting of a halogen group, an alkyl group having a carbon number of 1 or more and 5 or less, a phenyl group, a hydroxy group, an alkoxy group having a carbon number of 1 or more and 3 or less, and a fluoroalkyl group having a carbon number of 1 or more and 10 or less. h is a number 1 or more and 3 or less, i is a number of 0 or more and less than 3, j is a number more than 0 and of 3 or less, and h+i+j=4. In addition, when there are a plurality of R⁵ and R⁶, each of them is independently selected from any of the substituents described above.

In the general formula (3), R⁷ is a substituent selected from a group consisting of a halogen group, an alkoxy group, and a hydroxy group. k is a number of 0 or more and less than 4, l is a number more than 0 and 4 or less, and k+l=4.

In this case, in the second constituent unit represented by the general formula (2), as theoretical values of h, i, and j, h is an integer of 1 to 3, i is an integer of 0 to 3, and j is an integer of 0 to 3. In addition, h+i+j=4 means that the sum of the theoretical value is 4. However, for example, in the value obtained by ²⁹Si NMR measurement, each of h, i, and j, is obtained as an average value, so that the average value h may be a decimal that would be 1 or more and 3 or less when rounded, i may be a decimal that would be 0 or more and 3 or less when rounded (where i<3.0), and j may be a decimal that would be 0 or more and 3 or less when rounded (where j≠0).

In the third constituent unit represented by the general formula (3), as theoretical values of k and l, k is integer of 0 to 4, and l is an integer of 0 to 4. In addition, k+l=4 means that the sum of the theoretical values is 4. However, for example, in the value obtained by ²⁹Si NMR measurement, each of k and l is obtained as an average value, so that the average value k may be a decimal that would be 0 or more and 4 or less when rounded (where k<4.0), and I may be a decimal that would be 0 or more and 4 or less when rounded (where l≠0).

When a polymer is obtained by a sol-gel reaction, the presence of a HFIP group in (A) can suppress precipitation of a component derived from a raw material of (B) containing a metal species with high EUV absorbance such as Fe, Co, Ni, Cu, Zn, Ga, Ge, Mo, Pd, Ag, Sn, Cs, Ba, W, and Hf, and consequently, it is considered that the resin composition and the photosensitive resin composition of the present invention can be obtained.

In addition. the presence of the HFIP group in (a) a polysiloxane compound including a constituent unit represented by the general formula (1), enhances compatibility with (b) a metalloxane compound including a constituent unit represented by the general formula (1-A), which contains a metal species with high EUV absorbance such as Fe, Co, Ni, Cu, Zn, Ga, Ge, Mo, Pd, Ag, Sn, Cs, Ba, W, and Hf, and it is considered to be capable of obtaining the resin composition and the photosensitive resin composition of the present invention, which contain these.

In addition, O_{g/2} in the general formula (1) is generally used as a representation of a compound with a siloxane bond, and the following general formula (1-1) represents the case where g is 1, the general formula (1-2) represents the case where g is 2, and the general formula (1-3) represents the case where g is 3. In the case where g is 1, it is positioned at the end of the siloxane chain in the compound with the siloxane bond.

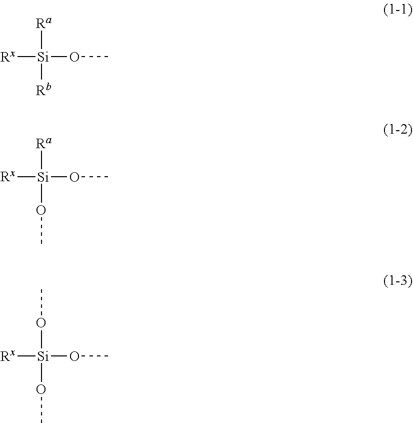

In the general formulas (1-1) to (1-3), R^{x} has the same meaning as R² in the general formula (1), and each R^{a} and R^{b} has the same meaning as R², R³, and OR⁴ in the general formula (1). The broken lines represent bonds to other Si atoms.

O_{j/2} in the general formula (2) is used as described above, and the following general formula (2-1) represents the case where j is 1, the general formula (2-2) represents the case where j is 2, and the general formula (2-3) represents the case where j is 3. In the case where j is 1, it is positioned at the end of the siloxane chain in the compound with the siloxane bond.

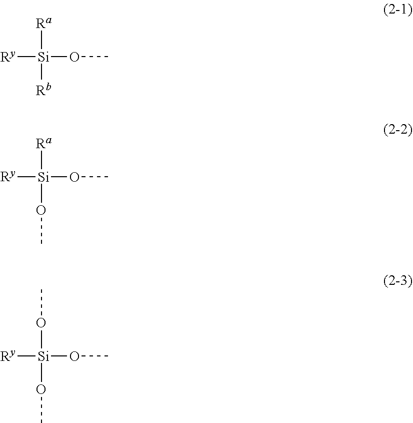

In general formulas (2-1) to (2-3), Ry has the same meaning as R⁵ in the general formula (2), and each R^{a}, R^{b} has the same meaning as R⁵, R⁶ in the general formula (2). The broken lines represent bonds to other Si atoms.

With respect to O_{l/2} in the general formula (3), O_{l/2} in the case where l=4 represents the following general formula (3-1). In the general formula (3-1), the broken line represents bonds with other Si atoms.

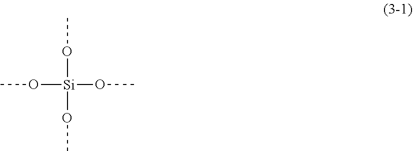

O_{4/2} in the above general formula (3) is generally called a Q4 unit, and shows a structure in which all four bonds of a Si atom form siloxane bonds. Although Q4 has been described above, the general formula (3) may contain a hydrolyzable and condensable group in the bond as in Q0, Q1, Q2, and Q3 units shown below. In addition, the general formula (3) may have at least one selected from a group consisting of Q1 to Q4 units.

Q0 unit: a structure in which all four bonds of a Si atoms are hydrolyzable and polycondensable groups (such as a halogenated group, alkoxy group, or hydroxyl group that can form siloxane bonds).

Q1 unit: a structure in which one of the four bonds of a Si atom forms a siloxane bond and the other three are all hydrolyzable and polycondensable groups.

Q2 unit: a structure in which two of the four bonds of a Si atom form a siloxane bond and the other two are all hydrolyzable and polycondensable groups.

Q3 unit: a structure in which three of the four bonds of a Si atom form a siloxane bond and the other one is the hydrolyzable and polycondensable group.

Hereinafter, the constituent unit represented by the general formula (1), the general formula (2), and the general formula (3) will be described in order.

### [Constituent Unit Represented By General Formula (1)]

[(R²)_{d}(R³)ₑ(OR⁴)_{f}SiO_{g/2}] (1)

In the general formula (1), R² is a group represented by the following general formula (1a).

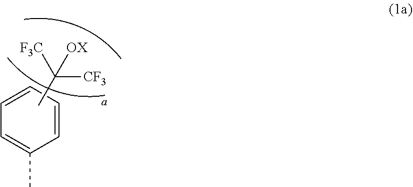

In the general formula (1a), X is a hydrogen atom or an acid-labile group.

a is a number of 1 to 5, and a broken line represents a bond.

In this case, the acid-labile group is a group that is eliminated by the action of a so-called acid and may contain an oxygen atom, a carbonyl bond, or a fluorine atom in part thereof.

A photoinduced compound containing a photoacid generator or a group capable of causing elimination due to an effect such as hydrolysis can be used as the acid-labile group without any particular limitation, and examples thereof include an alkyl group, alkoxycarbonyl group, acetal group, silyl group, and an acyl group.

Examples of the alkyl group include tert-butyl group, tert-amyl group, 1,1-dimethylpropyl group, 1-ethyl-1-methylpropyl group, 1,1-dimethylbutyl group, allyl group, 1-pyrenylmethyl group, 5-dibenzosuberyl group, triphenylmethyl group, 1-ethyl-1-methylbutyl group, 1,1-diethylpropyl group, 1,1-dimethyl-1-phenylmethyl group, 1-methyl-1-ethyl-1-phenylmethyl group, 1,1-diethyl-1-phenylmethyl group, 1-methylcyclohexyl group, 1-ethylcyclohexyl group, 1-methylcyclopentyl group, 1-ethylcyclopentyl group, 1-isobornyl group, 1-methyladamantyl group, 1-ethyladamantyl group, 1-isopropyladamantyl group, 1-isopropylnorbornyl group, 1-isopropyl-(4-methylcyclohexyl) group, and the like. The alkyl group is preferably a tertiary alkyl group, more preferably a group represented by —CR^{p}R^{q}R^{r} (R^{p}, R^{q}, and R^{r} are each independently a linear or branched alkyl group, a monocyclic or polycyclic cycloalkyl group, an aryl group or an aralkyl group, and two of R^{p}, R^{q}, and R^{r} may be bonded to form a ring structure).

Examples of the alkoxycarbonyl group include tert-butoxycarbonyl group, tert-amyloxycarbonyl group, methoxycarbonyl group, ethoxycarbonyl group, and i-propoxycarbonyl group. An acetal group includes methoxymethyl group, ethoxyethyl group, butoxyethyl group, cyclohexyloxyethyl group, benzyloxyethyl group, phenethyloxyethyl group, ethoxypropyl group, benzyloxypropyl group, phenethyloxypropyl group, ethoxybutyl group, ethoxyisobutyl group, and the like.

Examples of the silyl group include trimethylsilyl group, ethyldimethylsilyl group, methydiethylsilyl group, triethylsilyl group, i-propyldimethylsilyl group, methyldi-i-propylsilyl group, tri-i-propylsilyl group, t-butyldimethylsilyl group, methyldi-t-butylsilyl group, tri-t-butylsilyl group, phenyldimethylsilyl group, methyldiphenylsilyl group, triphenylsilyl group, and the like.

Examples of the acyl group include acetyl group, propionyl group, butyryl group, heptanoyl group, hexanoyl group, valeryl group, pivaloyl group, isovaleryl group, lauroyl group, myristoyl group, palmitoyl group, stearoyl group, oxalyl group, malonyl group, succinyl group, glutaryl group, adipoyl group, pimeloyl group, suberoyl group, azelaoyl group, sebacoyl group, acryloyl group, propioloyl group, methacryloyl group, crotonoyl group, oleoyl group, maleoyl group, fumaroyl group, mesaconoyl group, camphoroyl group, benzoyl group, phthaloyl group, isophthaloyl group, terephthaloyl group, naphthoyl group, toluoyl group, hydroatropoyl group, atropoyl group, cinnamoyl group, furoyl group, tenoyl group, nicotinoyl group, isonicotinoyl group, and the like.

Among them, tert-butoxycarbonyl group, methoxymethyl group, ethoxyethyl group, and trimethylsilyl group are generally preferable. Furthermore, it is also possible to use those in which part or all of the hydrogen atoms of these acid-labile groups are substituted with fluorine atoms. These acid-labile groups may be used in a single type or in a plurality of types.

Particularly preferred structures of the acid-labile group include a structure represented by the following general formula (ALG-1) and a structure represented by the following general formula (ALG-2).

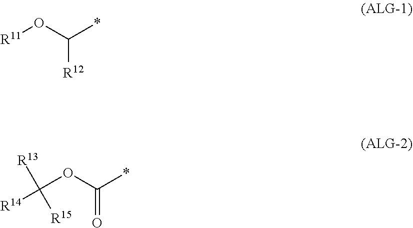

In the general formula (ALG-1) and the general formula (ALG-2), R¹¹ is a linear alkyl group having a carbon number of 1 to 10, a branched alkyl group having a carbon number of 3 to 10 or a cyclic alkyl group having a carbon number of 3 to 10, and an aryl group having a carbon number of 6 to 20 or an aralkyl group having a carbon number of 7 to 21. R¹² is a hydrogen atom, a linear alkyl group having a carbon number of 1 to 10, a branched alkyl group having a carbon number of 3 to 10 or a cyclic alkyl group having a carbon number of 3 to 10, and an aryl group having a carbon number of 6 to 20 or an aralkyl group having a carbon number of 7 to 21. R¹³, R¹⁴, and R¹⁵ are, independently, a linear alkyl group having a carbon number of 1 to 10, a branched alkyl group having a carbon number of 3 to 10 or a cyclic alkyl group having a carbon number of 3 to 10, and an aryl group having a carbon number of 6 to 20 or an aralkyl group having a carbon number of 7 to 21. Two of R¹³, R¹⁴, and R¹⁵ may be bonded to each other to form a ring. * represents a bonding site with an oxygen atom.

Each R³ is independently selected from a group consisting of a hydrogen atom, an alkyl group having a carbon number of 1 or more and 5 or less, a phenyl group, and a fluoroalkyl group having a carbon number of 1 or more and 10 or less. Each R⁴ is independently a hydrogen atom or an alkyl group having a carbon number of 1 or more and 5 or less.

d is a number of 1 or more and 3 or less, e is a number of 0 or more and 2 or less, f is a number of 0 or more and less than 3, g is a number more than 0 and 3 or less, and d+e+f+g=4.

When there is a plurality of R¹³, R¹⁴, and R¹⁵, each of them is independently selected from any of the substituents described above.

Specific examples of R³ in the general formula (1) include a hydrogen atom, methyl group, ethyl group, 3,3,3-trifluoropropyl-group, and phenyl group. In addition, specific examples of R⁴ include a hydrogen atom, methyl group, and ethyl group. In the theoretical values of d, e, f, and g, d is preferably an integer of 1 or 2. e is preferably an integer of 0 or more and 2 or less, more preferably an integer of 0 or 1. f is preferably an integer of 0 or more and 2 or less, more preferably an integer of 0 or 1. g is preferably an integer of 1 to 3, more preferably an integer of 2 or 3. a is preferably 1 or 2.

In addition, d is preferably a number of 1 or more and 2 or less. e is preferably a number of 0 or more and 2 or less, more preferably 0 or more and 1 or less. f is preferably a number of 0 or more and 2 or less, more preferably 0 or more and 1 or less. g is preferably a number of 1 or more and 3 or less, more preferably 2 or more and 3 or less.

Among them, from the viewpoint of manufacturability, the number of HFIP group-containing aryl groups represented by the general formula (1a) in the general formula (1) is preferably 1. That is, the constituent unit in which d is 1 is a particularly preferable example of the constituent unit of the general formula (1).

The group represented by the general formula (1a) in the general formula (1) is particularly preferably any of the groups represented by the general formulas (1aa) to (1ad).

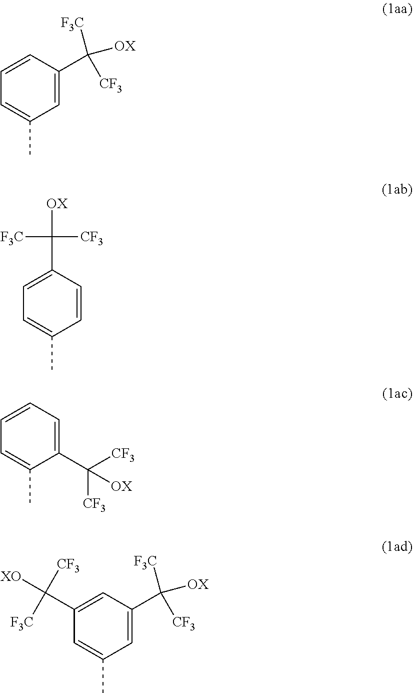

In the general formulas (1aa) to (1ad), the broken line represents bonds.

In an embodiment, the first constituent unit represented by formula (1) preferably consists of a single constituent unit. In this case, “consists of a single constituent unit” means that it consist of the constituent unit in which the number of a, the number of d, substituent species of R³ and its number e, substituent species of OR⁴ (excluding the hydroxy group and the alkoxy group) and its number f (excluding the number of the hydroxy group and the alkoxy group among f) in the general formula (1) are the same.

[Constituent Unit Represented by General Formula (2)]

[(R⁵)ₕ(R⁶)ᵢSiO_{j/2}] (2)

In the general formula (2), R⁵ is a substituent selected from monovalent organic groups having a carbon number of 1 or more and 30 or less and substituted by any of an epoxy group, oxetane group, acryloyl group, methacryloyl group, or lactone group.

R⁶ is a hydrogen atom, or a substituent selected from a group consisting of a halogen group, an alkyl group having a carbon number of 1 or more and 5 or less, a phenyl group, a hydroxy group, an alkoxy group having a carbon number of 1 or more and 3 or less, and a fluoroalkyl group having a carbon number of 1 or more and 10 or less.

h is a number 1 or more and 3 or less, i is a number of 0 or more and less than 3, j is a number more than 0 and 3 or less, and h+i+j=4.

When there is a plurality of R⁵ and R⁶, each of them is independently selected from the substituents described above.

In the theoretical values of h, i, and j in the general formula (2), i is preferably an integer of 0 or more and 2 or less, more preferably an integer of 0 or 1. j is preferably an integer of 1 to 3, more preferably an integer of 2 or 3. In addition, from the viewpoint of availability, the value of h is particularly preferably 1. Among these, a constituent unit in which h is 1, i is 0, and j is 3 is particularly preferred as the constituent unit of the general formula (2). Specific examples of R⁶ include a hydrogen atom, methyl group, ethyl group, phenyl group, methoxy group, ethoxy group, and a propoxy group.

In addition, h is preferably a number of 1 or more and 2 or less, more preferably 1. i is preferably a number of 0 or more and 2 or less, more preferably 0 or more and 1 or less. j is preferably a number of 1 or more and 3 or less, more preferably 2 or more and 3 or less.

In the case where R⁵ group of the second constituent unit represented by the general formula (2) includes an epoxy group, oxetane group, or lactone group, it is possible to impart good adhesion to the cured film or the patterned cured film obtained from the resin composition or the photosensitive resin composition, which is an embodiment, with various substrates containing silicon, glass, resin, or the like on the contact surface. In addition, in the case where R⁵ group contains an acryloyl group or methacryloyl group, a highly curable film is obtained, and good solvent resistance is obtained. In the case where R⁵ group includes an epoxy group or oxetane group, R⁵ group is preferably a group represented by the following general formulas (2a), (2b), and (2c).

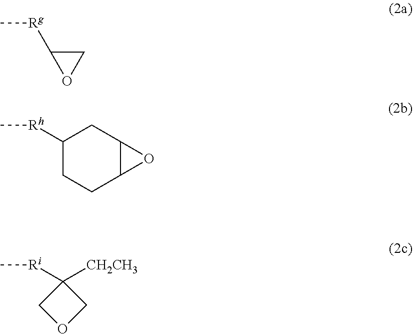

In the general formulas (2a), (2b), and (2c), each R^{g}, R^{h}, Rⁱ independently a divalent linking group. A broken line represents a bond.

In this case, in the case where R^{g}, R^{h}, and Rⁱ are divalent linking groups, the divalent linking group includes, for example, an alkylene group having a carbon number of 1 to 20, and may include one or more sites forming an ether bond. In the case where the number of carbon atoms is 3 or more, the alkylene group may be branched, or separate carbons may be connected to each other to form a ring. In the case where the number of carbon atoms is 2 or more, oxygen may be inserted between carbon and carbon and may include one or more sites forming an ether bond, and these are preferable examples as a divalent linking group.

Among the second constituent units represented by the general formula (2), the particularly preferred one is exemplified by the raw material alkoxysilane, and examples thereof include 3-glycidoxypropyltrimethoxysilane (manufactured by Shin-Etsu Chemical Co., Ltd., product name: KBM-403), 3-glycidoxypropyltriethoxysilane (manufactured by Shin-Etsu Chemical Co., Ltd., product name: KBE-403), 3-glycidoxypropylmethyldiethoxysilane (manufactured by Shin-Etsu Chemical Co., Ltd., product name: KBE-402), 3-glycidoxypropylmethyldimethoxysilane (manufactured by Shin-Etsu Chemical Co., Ltd., product name: KBM-402), 2-(3,4-epoxycyclohexyl)ethyltrimethoxysilane (manufactured by Shin-Etsu Chemical Co., Ltd., product name: KBM-303), 2-(3,4-epoxycyclohexyl)ethyltriethoxysilane 8-glycidoxyoctyltrimethoxysilane (manufactured by Shin-Etsu Chemical Co., Ltd., product name: KBM-4803), [(3-ethyl-3-oxetanyl)methoxy]propyltrimethoxysilane, [(3-ethyl-3-oxetanyl)methoxy]propyltriethoxysilane, and the like.

In the case where R⁵ group includes an acryloyl group or methacryloyl group, it is preferably a group selected from the following general formulas (3a) and (4a).

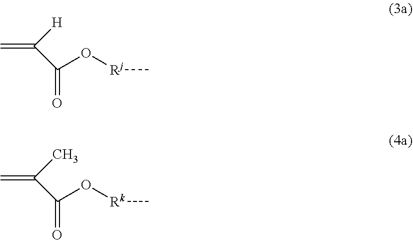

In the general formula (3a) and (4a), each R^{j} and R^{k} is independently a divalent linking group. A broken line represents a bond.

Preferred examples in the case where R^{j} and R^{k} are divalent linking groups include those listed as preferred groups in R^{g}, R^{h}, and Rⁱ.

Among the second constituent units represented by the general formula (2), the particularly preferred one is exemplified by the raw material alkoxysilane, and examples thereof include 3-methacryloxypropyltrimethoxysilane (manufactured by Shin-Etsu Chemical Co., Ltd., product name: KBM-503), 3-methacryloxypropyltriethoxysilane (manufactured by Shin-Etsu Chemical Co., Ltd., product name: KBE-503), 3-methacryloxypropylmethyldimethoxysilane (manufactured by Shin-Etsu Chemical Co., Ltd., product name: KBM-502), 3-methacryloxypropylmethyldiethoxysilane (manufactured by Shin-Etsu Chemical Co., Ltd., product name: KBE-502), 3-acryloxypropyltrimethoxysilane (manufactured by Shin-Etsu Chemical Co., Ltd., product name: KBM-5103), 8-methacryloxyoctyltrimethoxysilane (manufactured by Shin-Etsu Chemical Co., Ltd., product name: KBM-5803), and the like.

In the case where R⁵ group includes a lactone group, if it is represented by R⁵—Si structure, it is preferably a group selected from the following general formulas (5-1) to (5-20), general formulas (6-1) to (6-7), general formulas (7-1) to (7-28), or general formulas (8-1) to (8-12).

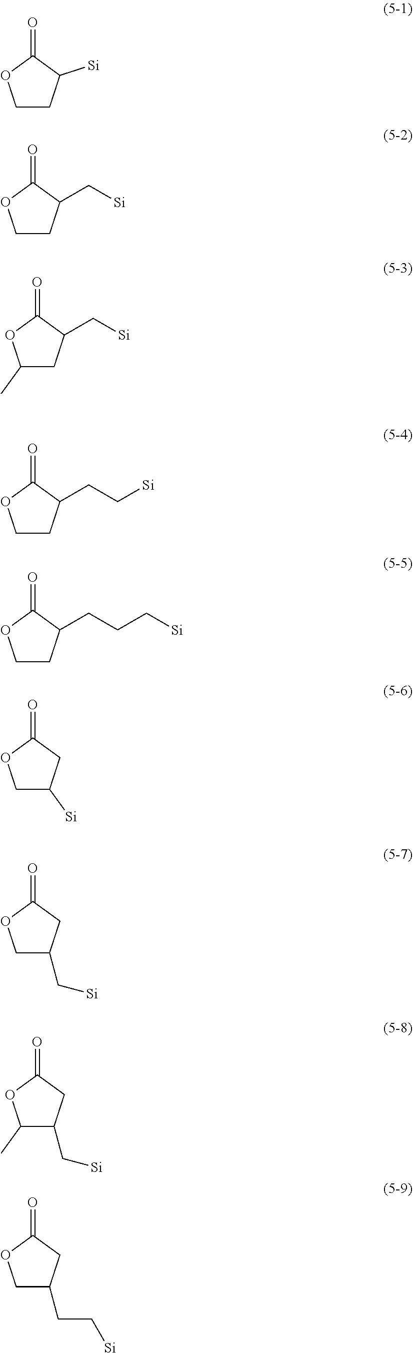

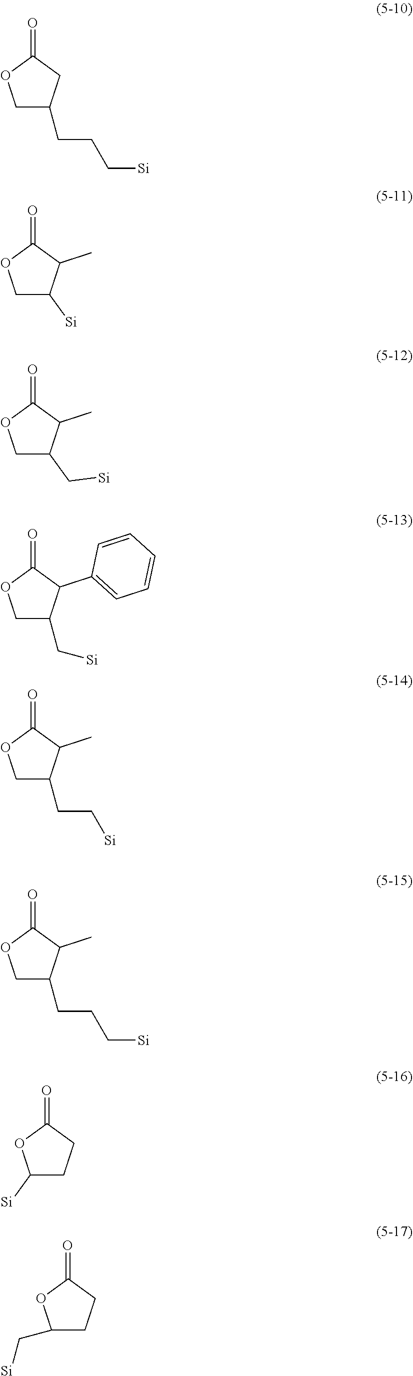

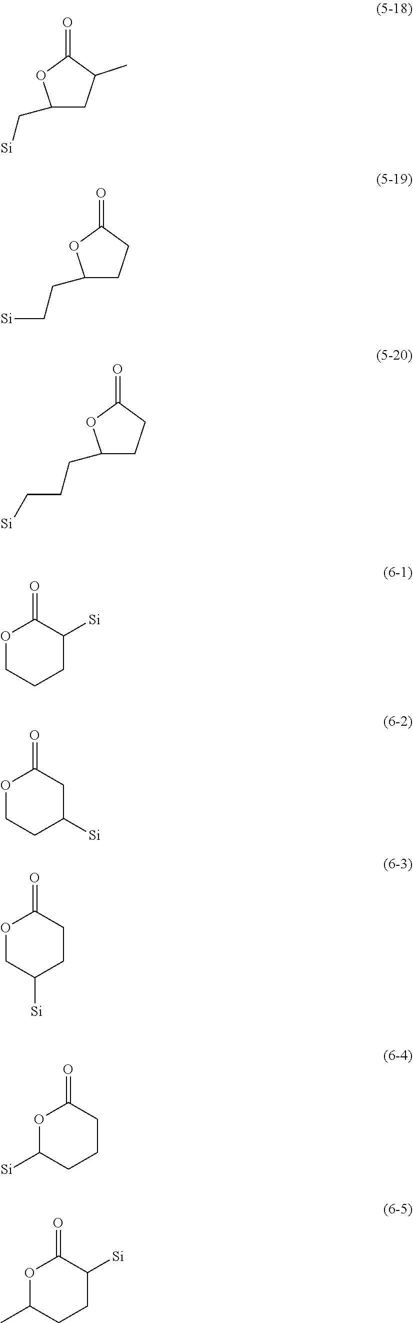

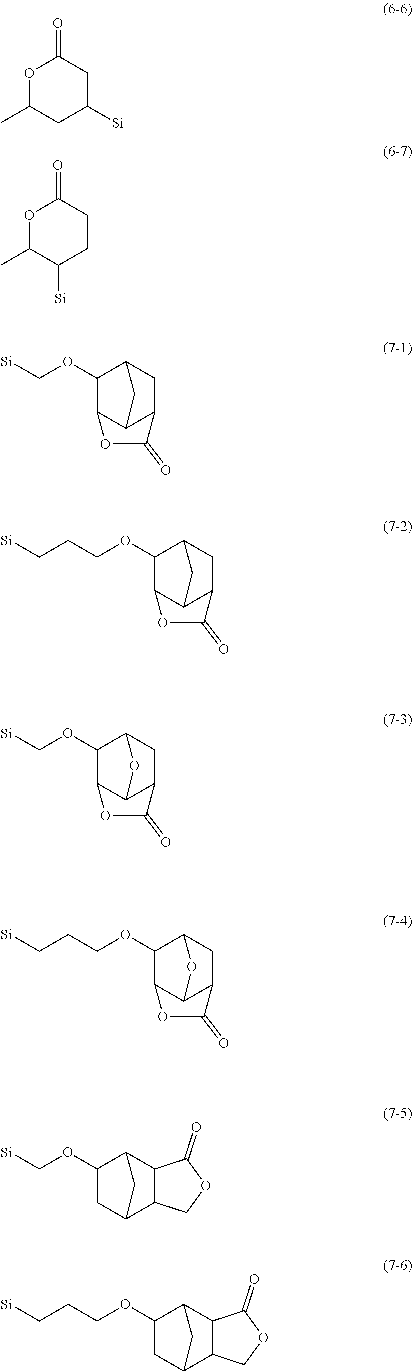

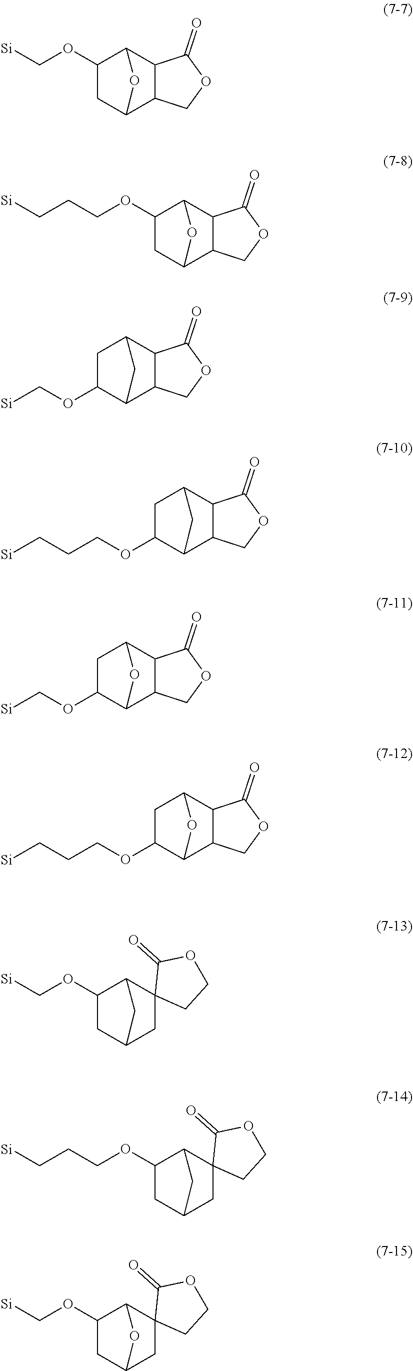

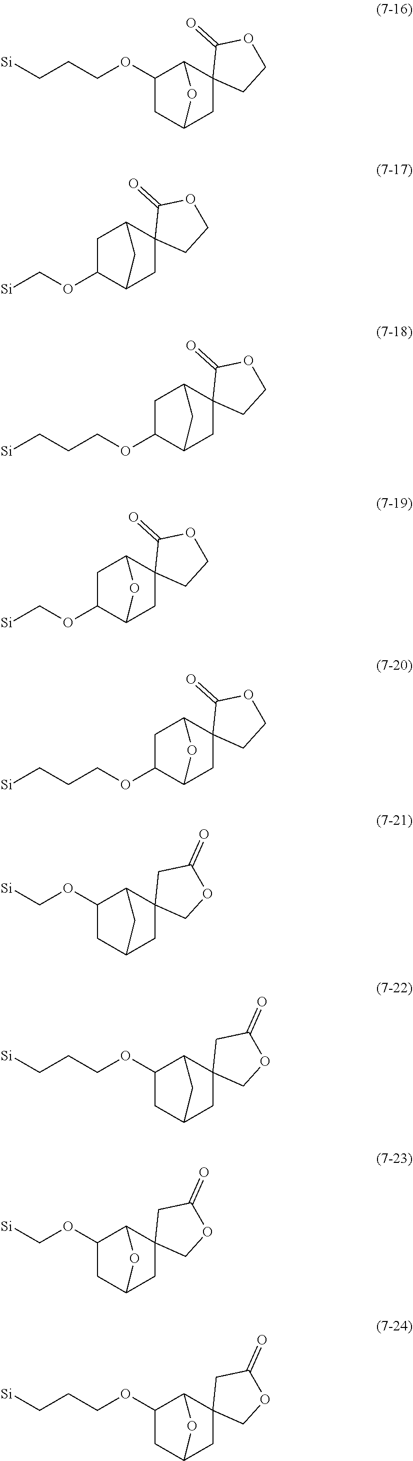

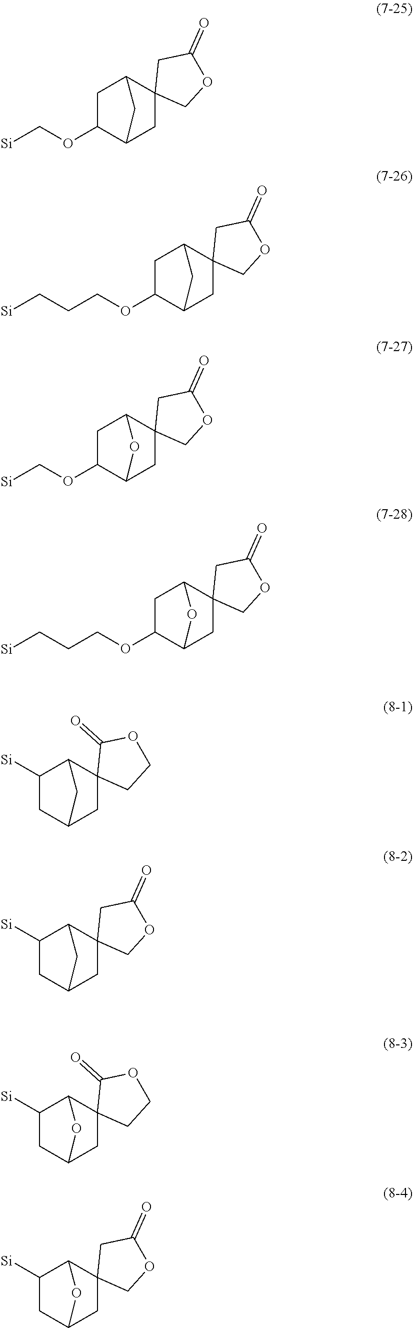

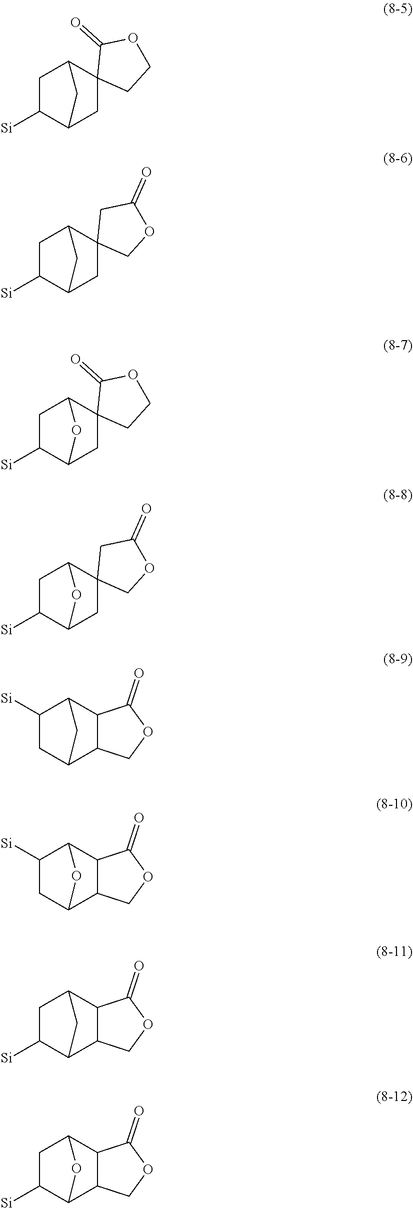

### [Third Constituent Unit Represented by General Formula (3)]

[(R⁷)ₖSiO_{l/2}] (3)

In the general formula (3), R⁷ is a substituent selected from a group consisting of a halogen group, alkoxy group, and hydroxy group.

k is a number of 0 or more and less than 4, l is a number more than 0 and 4 or less, and k+l=4.

In addition, k is preferably a number of 0 or more and 3 or less. I is preferably a number of 1 or more and 4 or less.

As described above, O_{l/2} in the general formula (3) may have at least one selected from a group consisting of Q1 to Q4 units. In addition, Q0 unit may be included.

Q0 unit: a structure in which all four bonds of a Si atom are hydrolyzable and polycondensable groups (such as a halogenated group, alkoxy group, or hydroxyl group that can form siloxane bonds).

Q1 unit: a structure in which one of the four bonds of a Si atom forms a siloxane bond and the other three are all hydrolyzable and polycondensable groups.

Q2 unit: a structure in which two of the four bonds of a Si atom form a siloxane bond and the other two are all hydrolyzable and polycondensable groups.

Q3 unit: a structure in which three of the four bonds of a Si atom form a siloxane bond and the other one is the hydrolyzable and polycondensable group.

Q4 unit: a structure in which all four bonds of a Si atom form a siloxane bond.

Since the third constituent unit represented by the general formula (3) has a configuration close to SiO₂ in which the organic components are eliminated as much as possible, it is possible to impart heat resistance, transparency, and chemical solution resistance to the cured film or the patterned cured film obtained from the resin composition or the photosensitive resin composition.

The third constituent unit represented by the general formula (3) can be incorporated into the polymer, or at least one of (a) a polysiloxane compound including a constituent unit represented by the general formula (1) and (b) a metalloxane compound including a constituent unit represented by the general formula (1-A) tetraalkoxysilane, tetrahalosilane (for example, tetrachlorosilane, tetramethoxysilane, tetraethoxysilane, tetra-n-propoxysilane, tetraisopropoxysilane, or the like) or an oligomer thereof as a raw material, and by conducting hydrolyzing and polycondensation of it.

Examples of the oligomer include a silicate compound such as silicate (pentamer on average, manufactured by TAMA CHEMICALS CO., LTD.), ethyl silicate 40 (pentamer on average, manufactured by COLCOAT CO., LTD.), silicate 45 (7-mer on average, manufactured by TAMA CHEMICALS CO., LTD.), M silicate 51 (4-mer on average, manufactured by TAMA CHEMICALS CO., LTD.), methyl silicate 51 (4-mer on average, manufactured by COLCOAT CO., LTD.), methyl silicate 53A (7-mer on average, manufactured by COLCOAT CO., LTD.), ethyl silicate 48 (10-mer on average, manufactured by COLCOAT CO., LTD.), EMS-485 (mixed product of ethyl silicate and methyl silicate, manufactured by COLCOAT CO., LTD.). From the viewpoint of ease of handling, a silicate compound is preferably used.

When the total amount of Si atoms contained in the polymer in the resin composition or at least one of (a) a polysiloxane compound including a constituent unit represented by the general formula (1), and (b) a metalloxane compound including a constituent unit represented by the general formula (1-A) is 100 mol %, the constituent unit (first constituent unit) represented by the general formula (1) is preferably contained in an amount of 5 mol % to 100 mol %. More preferably, it is contained in an amount of 8 mol % to 100 mol %.

In addition, in the case where the polymer or at least one of (a) a polysiloxane compound including a constituent unit represented by the general formula (1) and (b) a metalloxane compound including a constituent unit represented by the general formula (1-A) includes the second constituent unit or the third constituent unit in addition to the first constituent unit, the ratio of Si atoms in each constituent unit in the polymer or at least one of (a) a polysiloxane compound including a constituent unit represented by the general formula (1) and (b) a metalloxane compound including a constituent unit represented by the general formula (1-A) is preferably in the range of 0 mol % to 80 mol % for the second constituent unit and 0 mol % to 90 mol % for the third constituent unit (where the total of the second constituent unit and the third constituent unit is 1 mol % to 95 mol %).

In addition, the second constituent unit may be more preferably 2 mol % to 70 mol %, still more preferably 5 mol % to 40 mol %.

In addition, the third constituent unit may be more preferably in the range of less than 5 mol % or more than 50 mol %, even more preferably less than 5 mol % or more than 60 mol %. In the case where the third constituent unit is less than 5 mol %, the lower limit is not limited, but may be, for example, preferably 0 mol % or more, and more preferably more than 0 mol %. In the case where the third constituent unit is more than 50 mol %, the upper limit is not limited, but may be, for example, 95 mol % or less.

For example, the mole % of a Si atom can be determined from the peak area ratio in ²⁹Si NMR.

### [Other Constituent Units (Optional Components)]

The polymer in the resin composition or at least one of (a) a polysiloxane compound including a constituent unit represented by the general formula (1) and (b) a metalloxane compound including a constituent unit represented by the general formula (1-A) may include other constituent units containing Si atoms (hereinafter, may be simply referred to as “optional components”) to adjust the solubility in a solvent (C) described later, the heat resistance, transparency, and the like when the cured film or the patterned cured film is formed, in addition to the aforementioned constituent units. For example, the optional components include chlorosilanes or alkoxysilanes. Chlorosilanes and alkoxysilanes may be referred to as “other Si monomers”.

Specific examples of the chlorosilane include dimethyldichlorosilane, diethyldichlorosilane, dipropyldichlorosilane, diphenyldichlorosilane, bis(3,3,3-trifluoropropyl)dichlorosilane, methyl(3,3,3-trifluoropropyl)dichlorosilane, methyltrichlorosilane, ethyltrichlorosilane, propyltrichlorosilane, isopropyltrichlorosilane, phenyltrichlorosilane, methylphenyltrichlorosilane, trifluoromethyltrichlorosilane, pentafluoroethyltrichlorosilane, and 3,3,3-trifluoropropyltrichlorosilane.

Examples of alkoxysilane include dimethyldimethoxysilane, dimethyldiethoxysilane, dimethyldipropoxysilane, dimethyldiphenoxysilane, diethyldimethoxysilane, diethyldiethoxysilane, diethyldipropoxysilane, diethyldiphenoxysilane, dipropyldimethoxysilane, dipropyldiethoxysilane, diphenyldimethoxysilane, diphenyldiethoxysilane, diphenyldiphenoxysilane, bis(3,3,3-trifluoropropyl)dimethoxysilane, methyl(3,3,3-trifluoropropyl)dimethoxysilane, methyltrimethoxysilane, ethyltrimethoxysilane, propyltrimethoxysilane, isopropyltrimethoxysilane, methylphenyldimethoxysilane phenyltrimethoxysilane, methyltriethoxysilane, methylphenyldiethoxysilane, ethyltriethoxysilane, propyltriethoxysilane, isopropyltriethoxysilane, phenyltriethoxysilane, methyltripropoxysilane, ethyltripropoxysilane, propyltripropoxysilane, isopropyltripropoxysilane, phenyltripropoxysilane, methyltriisopropoxysilane, ethyltriisopropoxysilane, propyltriisopropoxysilane, isopropyltriisopropoxysilane, phenyltriisopropoxysilane, trifluoromethyltrimethoxysilane, pentafluoroethyltrimethoxysilane, 3,3,3-trifluoropropyltrimethoxysilane, and 3,3,3-trifluoropropyltriethoxysilane.

The optional components described above may be used alone or in a mixture of two or more thereof.

Among them, for the purpose of enhancing the heat resistance and transparency of the obtained patterned cured film, phenyltrimethoxysilane, phenyltriethoxysilane, methylphenyldimethoxysilane, and methylphenyldiethoxysilane are preferable, and for the purpose of enhancing the flexibility of the obtained patterned cured film to prevent cracks, dimethyldimethoxysilane and dimethyldiethoxysilane are preferable.

When the total amount of Si atoms contained in the polymer in the resin composition or at least one of (a) a polysiloxane compound including a constituent unit represented by the general formula (1) and (b) a metalloxane compound including a constituent unit represented by the general formula (1-A) is 100 mol %, the ratio of Si atoms contained as an optional component is not particularly limited, but may be, for example, 0 mol % to 99 mol %, preferably 0 mol % to 95 mol %, and more preferably 10 mol % to 85 mol %.

### [(B) Constituent Unit Represented by General Formula (1-A)]

(B) is a constituent unit represented by the following general formula (1-A).

In addition, (b) is metalloxane compound including a constituent unit represented by the following general formula (1-A).

[(R¹)_{b}MO_{c/2}] (1-A)

In the general formula (1-A), M is at least one selected from a group consisting of Fe, Co, Ni, Cu, Zn, Ga, Ge, Mo, Pd, Ag, Sn, Cs, Ba, W, and Hf, and each R₁ is independently a hydrogen atom, hydroxyl group, halogen group, an alkoxy group having a carbon number of 1 or more and 5 or less, an alkyl group having a carbon number of 1 or more and 5 or less, a phenyl group, and a fluoroalkyl group having a carbon number of 1 or more and 10 or less. b is a number of 0 or more and less than 4, c is a number more than 0 and 4 or less, and b+c=3 or 4.

In this case, in the constituent unit represented by the general formula (1-A), as theoretical values of b and c, integers of 0 to 4, and c is an integer of 0 to 4. In addition, b+c=3 or 4 means that the sum of the theoretical values is 3 or 4. However, for example, in the value obtained by a polynuclear NMR measurement capable of measuring Ti, Zr, Al, Hf, In, Sn or the like, each of b and c obtained as an average value, so that b of the average value may be a decimal that would be 0 or more and 4 or less when rounded (where b<4.0), and c may be a decimal that would be 0 or more and 4 or less when rounded (where c≠0). In addition, the theoretical value c=0 indicates that the constituent unit is a monomer, and the average value c≠0 indicates that all of the compounds are not monomers. Therefore, as a theoretical value, c is an integer of 0 to 4, and as a value obtained by measuring the polynuclear NMR, c is a decimal that would be 0 or more and 4 or less when (where c≠0) indicates that a compound containing a constituent unit represented by the general formula (1-A) may contain a monomer, but not all of the constituent units are monomers.

The constituent unit represented by the general formula (1-A) can be incorporated into the polymer or (b) the metalloxane compound having the constituent unit represented by the general formula (1-A) by using an alkoxy compound and a halogen compound containing a metal selected from the group consisting of Fe, Co, Ni, Cu, Zn, Ga, Ge, Mo, Pd, Ag, Sn, Cs, Ba, W, and Hf or an oligomer thereof as a raw material, and hydrolyzation and polycondensation of the raw material.

Among them, an alkoxy compound having a carbon number of 1 or more and 5 or less and a halogen compound in which a halogen species is chlorine are preferable. With respect to the metal species, Ge, Mo, or W that can be easily removed by a fluorine-based etching gas is preferable. R¹ is preferably a hydroxyl group, halogen group, an alkoxy group having a carbon number of 1 or more and 5 or less, an alkyl group having a carbon number of 1 or more and 5 or less, or a phenyl group.

If the monomer that gives the constituent unit represented by the general formula (1-A) is exemplified by alkoxy compounds, examples thereof include germanium tetramethoxide, germanium tetraethoxide, germanium tetrapropoxide, germanium tetrabutoxide, germanium tetraamyloxide, germanium tetrahexyloxide, germanium tetracyclopentoxide, germanium tetracyclohexyloxide, germanium tetraaryloxide, germanium tetraphenoxide, germanium (mono, di, or tri) methoxy (mono, di, or tri) ethoxide, germanium (mono, di, or tri) ethoxy (mono, di, or tri) propoxide, molybdenum tetraethoxide, tungsten tetraethoxide, and tungsten tetraphenoxide.

In addition, if the monomer that gives the constituent unit represented by the general formula (1-A) is exemplified by halogen compounds, examples thereof include germanium tetrachloride, germanium tetrabromide, germanium methyltrichloride, and germanium phenyltrichloride.

The content of (B) in the polymer can be appropriately selected. For example, when the sum of the components (A) and (B) is 100% by mass, it is preferable that (B) is 1% by mass to 90% by mass because it is easy to adjust the desired EUV photosensitivity when the cured film or the patterned cured film is formed. More preferably it may be 10% by mass to 80% by mass.

Similarly, the content of (b) relative to the total amount of (a) and (b) can be appropriately selected. For example, when the sum of (a) and (b) is 100% by mass, it is preferable that (b) is 1% by mass to 90% by mass because it is easy to adjust the desired EUV photosensitivity when the cured film or the patterned cured film is formed. More preferably it may be 10% by mass to 80% by mass.

In addition, the content of (B) contained in the resin composition is preferably such that the total content of M atoms in the general formula (1-A) is 0.3 atm % or more and less than 20 atm % when the cured film obtained by curing the resin composition is measured by X-ray photoelectron spectroscopy, from the viewpoint of improving EUV photosensitivity and improving the etch selectivity.

Similarly, the content of (b) contained in the resin composition is preferably such that the total content of M atoms in the general formula (1-A) is 0.3 atm % or more and less than 20 atm % when the cured film obtained by curing the resin composition is measured by X-ray photoelectron spectroscopy, from the viewpoint of improving EUV photosensitivity and improving the etch selectivity.

In the present specification, the content of each element is measured by X-ray photoelectron spectroscopy as the abundance ratio of the detected elements excluding the hydrogen atom. Specifically, the content of the elements can be measured using a photoelectron spectrometer (XPS) manufactured by JEOL Ltd. as a device, for example, JPS-9000MC, using MgKα (1253.6 eV) as an X-ray source, and the measurement range can be measured under the condition of a diameter of 6 mm.

### [(C) Solvent]

In an embodiment, the resin composition further includes:

(C) a solvent.

(C) The solvent may include at least one compound selected from a group consisting of propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols, glycol ethers, and glycol ether esters.

Specific examples of the glycol, glycol ether, and glycol ether ester include CELTOL (registered trademark) manufactured by Daicel Corporation and HISOLV (registered trademark) manufactured by TOHO CHEMICAL INDUSTRY COMPANY, LIMITED. Examples thereof include, but not limited to, cyclohexanol acetate, dipropylene glycol dimethyl ether, propylene glycol diacetate, dipropylene glycol methyl-n-propyl ether, dipropylene glycol methyl ether acetate, 1,4-butanediol diacetate, 1,3-butylene glycol diacetate, 1,6-hexanediol diacetate, 3-methoxybutylacetate, ethylene glycol monobutyl ether acetate, diethylene glycol monoethyl ether acetate, diethylene glycol monobutyl ether acetate, triacetin, 1,3-butylene glycol, propylene glycol-n-propyl ether, propylene glycol-n-butyl ether, dipropylene glycol methyl ether, dipropylene glycol ethyl ether, dipropylene glycol-n-propyl ether, dipropylene glycol-n-butyl ether, tripropylene glycol methyl ether, tripropylene glycol-n-butyl ether, triethylene glycol dimethyl ether, diethylene glycol butyl methyl ether, tripropylene glycol dimethyl ether, and triethylene glycol dimethyl ether.

In an embodiment, when the resin composition or the photosensitive resin composition is 10 parts by mass, the amount of the (C) solvent contained in the resin composition or the photosensitive resin composition is preferably 50 parts by mass or more and 500 parts by mass or less, and more preferably 80 parts by mass or more and 400 parts by mass or less. When the content of the solvent is within the range described above, it is easy to apply and form a resin film uniformized with an appropriate thickness. In addition, the (C) solvent may be used by combining two or more of the above solvents.

### [Additive (Optional Components)]

In an embodiment, the resin composition may contain the following components as additives to the extent that the excellent properties of the resin composition are not significantly impaired.

For example, an additive such as a surfactant may be included in order to improve coatability, leveling property, film formability, storage stability, defoaming property, and the like. Specific examples thereof include commercially available surfactants, product name MEGAFAC, manufactured by DIC Corporation, product number: F142D, F172, F173, or F183, product name: Fluorad, manufactured by 3M Japan Limited., product number: FC-135, FC-170C, FC-430, or FC-431, product name: SURFLON, manufactured by AGC Seimi Chemical Co., Ltd., product number: S-112, S-113, S-131, S-141, or S-145, or product name: SH-28PA, SH-190, SH-193, SZ-6032, or SF-8428, manufactured by Toray Dow Corning Silicone Co., Ltd.

In the case where these surfactants are added, the blending amount thereof is preferably 0.001 parts by mass or more and 10 parts by mass or less with respect to 100 parts by mass of (A) or (a). In addition, MEGAFAC is a product name of a fluorine-based additive (surfactant/surface modifier) manufactured by DIC Corporation, Fluorad is a product name of a fluorine-based surfactant manufactured by 3M Japan Limited., and SURFLON is a product name of a fluorine-based surfactant manufactured by AGC Seimi Chemical Co., Ltd., and each of them is registered as a trademark.

In order to improve the chemical solution resistance of the obtained cured film or patterned cured film, a curing agent can be blended as another component. Examples of the curing agent include a melamine curing agent, a urea resin curing agent, a polybasic acid curing agent, an isocyanate curing agent, and an epoxy curing agent. It is considered that the curing agent mainly reacts with a hydroxy group or alkoxy group contained in (A), (B), or (a), (b) to form a crosslinked structure.

Specific examples thereof include isocyanates such as isophorone diisocyanate, hexamethylene diisocyanate, tolylene diisocyanate, or diphenylmethane diisocyanate, and isocyanurates thereof, blocked isocyanates thereof, or a biurets thereof. amino compounds such as melamine resins such as alkylated melamine, methylol melamine, imino melamine, and urea resins or epoxy curing agents having two or more epoxy groups obtained by reacting polyhydric phenol such as bisphenol A with epichlorohydrin. Specifically, a curing agent having a structure represented by the general formula (11) is more preferable, and specifically, a melamine derivative represented by the general formulas (11a) to (11d) or a urea derivative (manufactured by SANWA Chemical Co., Ltd.) is exemplified (in the general formula (11), a broken line means a bond).

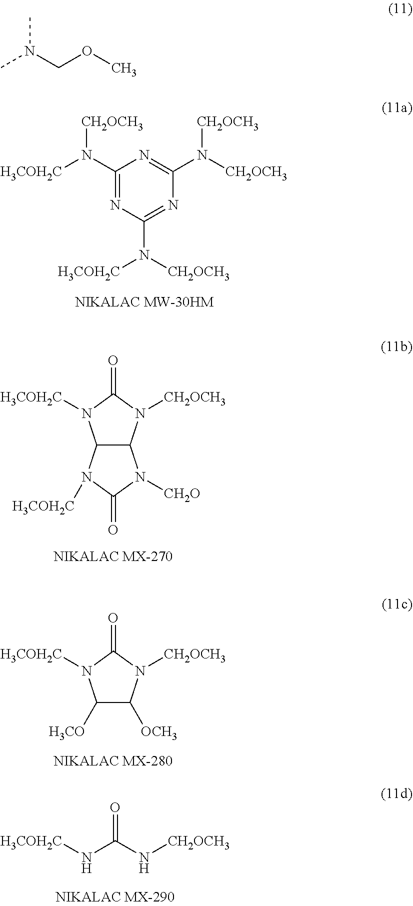

In the case where these curing agents are added, the blending amount thereof is preferably 0.001 parts by mass or more and 10 parts by mass or less with respect to 100 parts by mass of (A) or (a).

### [Method for Producing Resin Composition]

### <1> Polycondensation Using Raw Material Monomers

A polymer including (A) and (B) described above may be produced by conducting hydrolysis and polycondensation of halosilanes represented by the general formula (9) and alkoxysilane represented by a general formula (10), which are raw materials of the first constituent unit, and a metal compound represented by the following general formula (1-2), which is a raw material of the constituent unit represented by the general formula (1-A), and may be used as a resin composition. Alternatively, the polymer may be subjected to at least one operation selected from a group consisting of dilution with a solvent, a concentration, an extraction, a water washing, an ion exchange resin purification, and a filtration (hereinafter, it may be simply referred to as “series of operations described later) to produce a resin composition.

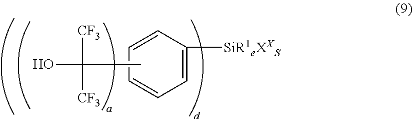

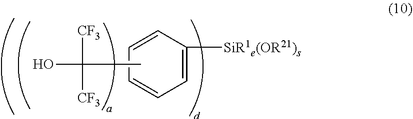

In the general formulas (9) and (10), X^{x} is a halogen atom, R²¹ is an alkyl group, a is an integer of 1 to 5, d is an integer of 1 to 3, e is an integer of 0 to 2, s is an integer of 1 to 3, and d+e+s=4.

In particular, from the viewpoint of ease of control of hydrolysis and polycondensation, a polymer including the constituent unit represented by the following general formula (1) and the constituent unit represented by the following general formula (1-A) can be produced by conducting hydrolysis and polycondensation of a silicon compound represented by the following general formula (1y) and a metal compound represented by the following general formula (1-2), and the polymer may be used as a resin composition. Alternatively, the polymer may be subjected to a series of operations described later to produce a resin composition.

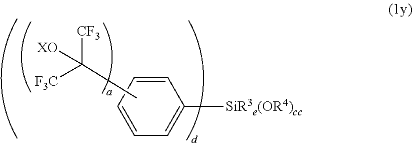

M(R⁸)ₘ(R⁹)ₙ (1-2)

In the general formula (1y), each R³ is independently a hydrogen atom, an alkyl group having a carbon number of 1 or more and 5 or less, a phenyl group, or a fluoroalkyl group having a carbon number of 1 or more and 10 or less.

Each R⁴ is independently a hydrogen atom or an alkyl group having a carbon number of 1 or more and 5 or less.

a is a number of 1 to 5. d is a number of 1 or more and 3 or less.

e is a number of 0 or more and 2 or less. cc is a number of 1 or more and 3 or less.

d+e+cc=4.

X is a hydrogen atom or an acid-labile group.

In the general formula (1-2), M is at least one selected from the group consisting of Fe, Co, Ni, Cu, Zn, Ga, Ge, Mo, Pd, Ag, Sn, Cs, Ba, W, and Hf.

Each R⁸ is independently a hydrogen atom, hydroxyl group, an alkyl group having a carbon number of 1 or more and 5 or less, a phenyl group, or a fluoroalkyl group having a carbon number of 1 or more and 10 or less.

R⁹ is an alkoxy having a carbon number of 1 to 5 or a halogen.

m is a number of 0 or more and 3 or less, n is a number of 1 or more and 4 or less, and m+n=3 or 4.

Preferred examples of the metal compound represented by the general formula (1-2) include that M is at least one selected from a group consisting of Ge, Mo, and W. R⁸ is a halogen group or an alkoxy group having a carbon number of 1 or more and 5 or less. Specific examples thereof include germanium tetramethoxide, germanium tetraethoxide, germanium tetrapropoxide, germanium tetrabutoxide, germanium tetraamyloxide, germanium tetrahexyloxide, germanium tetracyclopentoxide, germanium tetracyclohexyloxide, germanium tetraaryloxide, germanium tetraphenoxide, germanium (mono, di, or tri) methoxy (mono, di, or tri) ethoxide, germanium (mono, di, or tri) ethoxy (mono, di, or tri) propoxide, molybdenum tetraethoxide, tungsten tetraethoxide, tungsten tetraphenoxide, germanium tetrachloride, germanium tetrabromide, germanium methyltrichloride, and germanium phenyltrichloride.

### <2>s Polycondensation Using Pre-Oligomerized Raw Material

The halosilanes represented by the general formula (9), which is a raw material of the first constituent unit, the alkoxysilane represented by the general formula (10), or the silicon compound represented by the general formula (1y) may be oligomerized by conducting hydrolysis and polycondensation in advance, and the resultant may be subjected to hydrolysis and polycondensation with the metal compound represented by the following general formula (1-2), which is a raw material of the constituent unit represented by the general formula (1-A), to produce a polymer having the above (A) and the above (B), which may be used as a resin composition. Alternatively, the polymer may be subjected to a series of operations described later to produce a resin composition.

In addition, the metal compound represented by the following general formula (1-2), which is a raw material of the constituent unit represented by the general formula (1-A), may be oligomerized by conducting hydrolysis and polycondensation in advance, and the resultant may be subjected to hydrolysis and polycondensation with halosilanes represented by the general formula (9), the alkoxysilane represented by the general formula (10), or the silicon compound represented by the general formula (1y) which are raw materials of the first constituent unit to produce a polymer having the above (A) and the above (B), which may be used as a resin composition. Alternatively, the polymer may be subjected to a series of operations described later to produce a resin composition.

In addition, the halosilanes represented by the general formula (9), the alkoxysilane represented by the general formula (10), or the silicon compound represented by the general formula (1y), which are raw materials of the first constituent unit, may be oligomerized by conducting hydrolysis and polycondensation in advance, and the metal compound represented by the following general formula (1-2), which is a raw material of the constituent unit represented by the general formula (1-A) may be oligomerized by conducting hydrolysis and polycondensation in advance, and both oligomers may be mixed and subjected to hydrolysis and polycondensation to produce a polymer having the above (A) and the above (B), which may be used as a resin composition. Alternatively, the polymer may be subjected to a series of operations described later to produce a resin composition.

It is preferred that the oligomers described above are a dimer to pentamer.

In the hydrolysis and polycondensation reaction in <1> and <2> described above, the above monomer for obtaining the second constituent unit, the above monomer for obtaining the third constituent unit, or the above other Si monomers, which are optional components, may be added as needed. In addition, the optional components may be added as pre-oligomerized components.

The hydrolysis and polycondensation reaction can be carried out by a general method in the hydrolysis and condensation reaction of halosilanes (preferably chlorosilane) and alkoxysilane.

As a specific example, an embodiment in which a monomer raw material is used will be described. First, halosilanes and alkoxysilane, which are the raw materials of (A) and (B), are collected in a predetermined amount in a reaction vessel at room temperature (in particular, an atmosphere temperature which is not heated or cooled, and is usually about 15° C. or more and about 30° C. or less; the same shall apply hereinafter), and then water for hydrolyzing halosilanes and alkoxysilane, a catalyst for causing the polycondensation reaction to proceed, and, if desired, a reaction solvent are added to the reaction vessel to form a reaction solution. In this case, the order in which the reaction materials are charged is not limited to this, and the reaction solution can be obtained by charging the reaction materials in any order. In the case where the optional components are used in combination, they may be added to the reaction vessel in the same manner as the halosilanes and alkoxysilane.

Then, the reaction solution is stirred to proceed with the hydrolysis and condensation reactions at a predetermined temperature for a predetermined period of time to obtain a resin composition containing a polymer including the above (A) and the above (B). The time required for the hydrolysis and condensation depends on the type of the catalyst, and is usually 3 hours or more and 24 hours or less, and the reaction temperature is room temperature (for example, 25° C.) or more and 200° C. or less. In the case where heating is performed, in order to prevent the unreacted raw material, water, the reaction solvent, and/or the catalyst in the reaction system from being distilled off to the outside of the reaction system, it is preferable that the reaction vessel is a closed system or a reflux device such as a condenser is attached to reflux the reaction system. After the reaction, from the viewpoint of handling of the resin composition, it is preferable to remove the water remaining in the reaction system, the alcohol to be formed, and the catalyst. The removal of water, alcohol, and catalyst may be carried out in an extraction operation, or a solvent such as toluene that does not adversely affect the reaction may be added to the reaction system and azeotropically removed in a Dean-Stark tube.

The amount of water used in the hydrolysis and condensation reaction is not particularly limited. From the viewpoint of reaction efficiency, the amount is preferably 0.01 times or more and 15 times or less with respect to the total number of moles of the hydrolyzable groups (an alkoxy group or halogen atom group, and in the case of including both, an alkoxy group and halogen atom group) contained in the alkoxysilane or halosilanes as the raw material.

The catalyst for carrying out the polycondensation reaction is not particularly limited, but an acid catalyst or a base catalyst is preferably used. Specific examples of the acid catalyst include hydrochloric acid, nitric acid, sulfuric acid, hydrofluoric acid, phosphoric acid, acetic acid, oxalic acid, trifluoroacetic acid, methanesulfonic acid, trifluoromethanesulfonic acid, camphorsulfonic acid, benzenesulfonic acid, tosylic acid, a polyvalent carboxylic acid such as formic acid, maleic acid, malonic acid, or succinic acid, or anhydrides thereof. Specific examples of the base catalyst include triethylamine, tripropylamine, tributylamine, tripentylamine, trihexylamine, triheptylamine, trioctylamine, diethylamine, triethanolamine, diethanolamine, sodium hydroxide, potassium hydroxide, sodium carbonate, and tetramethylammonium hydroxide. The amount of the catalyst to be used is preferably 0.001 times or more and 0.5 times or less with respect to the total number of moles of the hydrolyzable groups (an alkoxy group or halogen atom group, and in the case of including both, an alkoxy group and halogen atom group when both are included) contained in the alkoxysilane and halosilanes as the raw material.

In the hydrolysis and condensation reaction, the reaction solvent is not necessarily used, and the raw material compound, water, and the catalyst can be mixed and hydrolyzed and condensed. On the other hand, when a reaction solvent is used, the type thereof is not particularly limited. Among them, from the viewpoint of solubility of the raw material compound, water, and a catalyst, a polar solvent is preferable, and an alcohol-based solvent is more preferable. Specific examples thereof include methanol, ethanol, 1-propanol, 2-propanol, 1-butanol, 2-butanol, diacetone alcohol, and propylene glycol monomethyl ether. When the reaction solvent is used, any amount necessary for the hydrolysis and condensation reaction to proceed in a homogeneous system can be used. In addition, (C) the solvent may be used as the reaction solvent.

### <3> Blend of (a) and (b) Obtained by Pre-Polymerization

A mixture containing the above (a) and (b) may be produced by mixing at least the above (a) and (b) obtained by polymerization in advance by a known method, and the mixture may be used as a resin composition. Alternatively, the resin composition may be produced by performing a series of operations described later on the mixture. At the time of mixing, it is preferable to perform dispersion so that precipitation of components derived from the raw materials does not occur. Therefore, (C) the solvent may be further contained. The HFIP group in the first constituent unit represented by the general formula (1) of (a) enhances compatibility with (b) containing a metal species with high EUV absorbance such as Fe, Co, Ni, Cu, Zn, Ga, Ge, M o, Pd, Ag, Sn, Cs, Ba, W, and Hf, and it is possible to realize a resin composition and a photosensitive resin composition that suppress precipitation of components derived from the raw material, in particular precipitation of (b).

### [Method for Synthesizing Raw Material Compound of Constituent Unit of General Formula (1)]

Alkoxysilanes represented by the general formula (10) or the general formula (1y) and halosilanes represented by the general formula (9), which are polymerization raw materials for providing the first constituent unit of the general formula (1), are known compounds described in International patent publication No. 2019/167770, and may be synthesized according to the description of publicly known literature.

In the hydrolysis and polycondensation described in <1> and <2>, the ratio of the raw material of the first constituent unit and the raw material of the constituent unit represented by the general formula (1-A) is preferably such that, when the sum of the first constituent unit and the constituent unit represented by the general formula (1-A) is 100% by mass, the constituent unit represented by the general formula (1-A) is 1% by mass to 90% by mass.

In addition, in a blend of (a) and (b) described in <3> above, when the sum of (a) and (b) is 100% by mass, the ratio of (b) is preferably 1% to 90% by mass.

In addition, the molecular weight of the polymer obtained in the above <1> and <2> may be 500 to 50,000, preferably 800 to 40,000, and more preferably 1,000 to 30,000 in terms of weight average molecular weight. The molecular weight can be within a desired range by adjusting the amount of the catalyst and the temperature of the polymerization reaction.

In addition, the molecular weight after the blending of (a) and (b) described in the above <3> may be 500 to 50,000, preferably 800 to 40,000, and more preferably 1,000 to 30,000 in terms of weight average molecular weight. The molecular weight can be set within a desired range by adjusting the mixing ratio of (a) and (b) and the molecular weight of each of (a) and (b).

In an embodiment, the addition of a chelator to the metal compound represented by the general formula (1-2) when conducting the hydrolysis and polycondensation or before conducting the hydrolysis and polycondensation in the above <1> or <2> is preferred because the reaction uniformity of the hydrolysis and polycondensation is improved.

In addition, the addition of a chelator to the metal compound represented by the general formula (1-2) when conducting the hydrolysis and polycondensation or before conducting the hydrolysis and polycondensation in obtaining the pre-polymerized (b) in the above <3> is preferred because the reaction uniformity of the hydrolysis and polycondensation is improved.

Examples of the chelator may include p-diketones such as acetylacetone, benzoylacetone, and dibenzoylmethane, and p-keto acid esters such as ethyl acetoacetate and ethyl benzoylacetate.

The “series of operations” described in the above <1> to <3> will be described.

One or more solvents selected from the above (C) solvent can be used as the solvent used for the dilution, and thus a detailed description thereof will be omitted. In addition, the concentration at which the polymer is diluted or concentrated with the solvent is not particularly limited as long as it is the concentration required for the resin composition. For example, the amount of the polymer may be 0.5 parts by mass or more and 100 parts by mass or less with respect to 100 parts by mass of the resin composition.

In addition, common methods such as evaporators may be used for the concentration.

In addition, a general method such as using a separation funnel may be used for the extraction. In the production of the polymer described above, the water remaining in the system after the hydrolysis and polycondensation reaction, the alcohol to be formed, and the catalyst may be removed by the extraction.

In the case where the polymer separates from water, the polymer may be washed with water, or the polymer described above may be dissolved in a solvent that separates from water to form an organic solution and washed with water.

In addition, ion exchange resin purification may be performed to reduce the metal content in the system by contacting with a commercially available ion exchange resin.

In addition, filtration may be performed to reduce insolubles such as particles in the system by general methods.

The atom represented by M in the general formula (1-A) and the Si atom in the general formula (1) are likely to form a bond via an oxygen atom, and a more uniform resin composition is easily obtained, so that <1> and <2> are preferred among the methods for producing the resin composition described in <1> to <3>, and <1> is particularly preferred.

### [Cured Film]

A cured film can be formed by applying the resin composition onto a substrate and curing the resin composition. In an embodiment, after the resin composition is applied onto a substrate, the resin composition is solidified by heating at a temperature of 80° C. or higher and 350° C. or lower to form the cured film.

### [Substrate Having Multiple Layers]

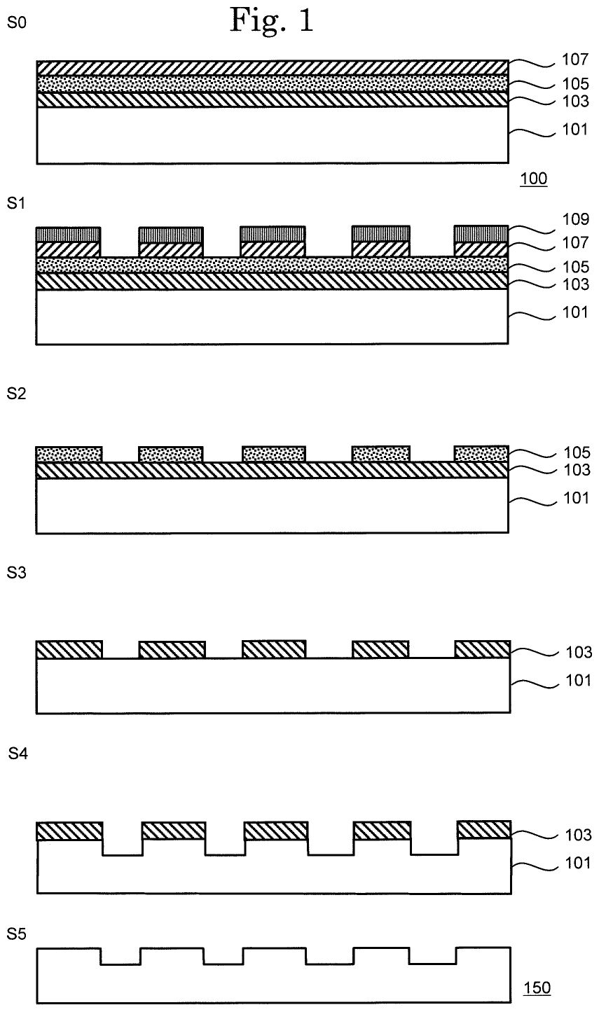

In an embodiment, a substrate having multiple layers in which a cured film obtained by curing the present resin composition is used as an underlayer film can be provided. S0 of FIG. 1 shows an example of a substrate 100 having multiple layers. For example, the substrate 100 having multiple layers includes an organic layer 103 onto a substrate 101, an underlayer film 105, which is a cured product of the above resin composition, on the organic layer 103, and a resist layer 107 on the underlayer film 105.

The substrate 101 is prepared. The substrate 101 may be selected from a silicon wafer, a metal, a glass, a ceramic, and a plastic substrate depending on the application of the substrate having the pattern to be formed. Specific examples of the substrate used in a semiconductor or a display include silicon, silicon nitride, glass, polyimide (Kapton), polyethylene terephthalate, polycarbonate, and polyethylene naphthalate. In addition, the substrate 101 may have any layer such as silicon, metal, glass, ceramic, or resin on the surface thereof, and “on the substrate” may be a surface of the substrate or via the layer.

An organic application liquid for forming the organic layer 103 is applied onto the substrate 101. The organic application liquid used to form the organic layer 103 includes, for example, an application liquid containing a novolak resin having a phenol structure, bisphenol structure, naphthalene structure, fluorene structure, and carbazole structure and the like, epoxy resin, urea resin, isocyanate resin, or polyimide resin but is not particularly limited thereto. In addition, a thickness of the organic layer 103 may be 5 nm or more and 20,000 nm or less.

A known coating method such as spin coating, dip coating, spray coating, bar coating, applicator, ink jet or roll coater can be used as a coating method on the substrate 101 without any particular limitation.

Thereafter, the substrate 101 coated with the organic material application liquid is heated, whereby the organic layer 103 can be obtained. In the heat treatment, the solvent may be removed to such an extent that the obtained organic layer 103 does not easily flow or deform, and it may be heated under conditions of, for example, 100° C. to 400° C. for 30 seconds or more and 30 minutes or less.

Next, the present resin composition is applied onto the organic layer 103 and cured, whereby the underlayer film 105 of the resist can be obtained. The coating method described above can be used as a method of applying the resin composition. In addition, the resin composition can be solidified by heating at a temperature of 80° C. or higher and 350° C. or lower to form the underlayer film 105.

In addition, a thickness of the underlayer film 105 can be 5 nm or more and 500 nm or less.

The resist layer 107 can be formed by applying and heating a resist liquid onto the underlayer film 105. The resist material that can be used for the substrate 100 having multiple layers is not particularly limited. In addition, in the present embodiment, the resist layer 107 may be formed of a positive resist material or a negative resist material. The substrate 100 having multiple layers according to the present embodiment can be formed through the above steps.

### [Patterning Method Using Substrate Having Multiple Layers]

Next, a patterning method using the substrate having multiple layers (also referred to as a “method of manufacturing a substrate having a pattern” in the present specification) will be described. FIG. 1 is a schematic diagram illustrating a method of manufacturing a substrate 150 having a pattern according to an embodiment of the present invention.

The method of manufacturing the substrate 150 having the pattern can include the following steps 0 to 5.

0th step: preparing the substrate 100 having multiple layers.

First step: exposing the resist layer 107 through a light-shielding plate (photomask) 109, and then developing the exposed resist layer 107 with a developer to obtain a pattern.

Second step: dry etching the underlayer film 105 through the pattern of the resist layer 107 to obtain the pattern of the underlayer film 105.

Third step: dry etching the organic layer 103 through the pattern of the underlayer film 105 to obtain the pattern of the organic layer 103.

Fourth step: dry etching the substrate 101 through the pattern of the organic layer 103 to obtain the pattern of the substrate 101.

Fifth step: removing the organic layer 103 to obtain the substrate 150 having a pattern.

### [0th Step]

The step of preparing the substrate 100 having multiple layers (step S0) may be performed according to the step of producing the substrate 100 having multiple layers described above, and a detailed explanation thereof will be omitted.

### [First Step]

Next, the substrate 100 having multiple layers prepared in the 0th step is shielded by the light-shielding plate (photomask) 109 having a desired shape for forming a desired pattern, and the resist layer 107 is irradiated with light and subjected to an exposure process to obtain the exposed resist layer 107. The exposed resist layer 107 includes an exposed portion and an unexposed portion.

A known method can be used for the exposure process. A light beam having wavelengths in the range of 1 nm to 600 nm can be used as a light source. Specifically, a low-pressure mercury lamp, a high-pressure mercury lamp, an ultra-high-pressure mercury lamp, a KrF excimer laser (wavelength 248 nm), an ArF excimer laser (wavelength 193 nm), an EUV beam (wavelength 6 nm to 27 nm, preferably 13.5 nm), or the like can be used. The exposure amount can be adjusted according to the type and amount of the photoinduced compound to be used, the producing process, and the like, and is not particularly limited, but may be about 1 to 10,000 mJ/cm², preferably about 10 to 5,000 mJ/cm².

In the present embodiment, the underlayer film 105 arranged directly below the resist layer 107 is formed of a resin composition which is a homogeneous solution containing a metal species with high EUV absorbance, so that secondary electrons from EUV photons can be returned from the underlayer film 105 to the resist layer 107 side to increase EUV photosensitivity.

After the exposure, post-exposure heating can be performed before the development step, if necessary. The temperature of the post-exposure heating may be set within a temperature range suitable for the resist material to be used, and the post-exposure heating may be performed within a time suitable for the resist material to be used, and these are not particularly limited.

Next, the exposed portion is removed by developing the exposed resist layer 107 obtained in the first step, so that a pattern having a desired shape can be formed (step S1). In addition, although FIG. 1 is an explanatory diagram of a method of producing a positive patterned cured film, when a negative patterned cured film is obtained, portions other than the exposed portion are removed by developing and are not shielded by the light-shielding plate 109, that is, the resist layer 107, which is a so-called exposed portion, becomes a pattern.

Development means to form a pattern by dissolving and washing and removing an unexposed portions or exposed portions using an alkaline solution as a developer.

The developer to be used is not particularly limited as long as it can remove a desired resist layer by a predetermined development method.

A known method such as an immersion method, a paddle method, or a spray method can be used as the development method, and the development time can be set according to the resist material. Thereafter, the desired resist layer 107 may be formed by washing, rinsing, drying, or the like as necessary.

### [Second Step]

Dry etching of the underlayer film 105 is performed through the pattern of the resist layer 107 (step S2). In the second step, dry etching of the underlayer film 105 can be performed with a fluorine-based gas. The pattern of the resist layer 107 serves as a protective film, and after dry etching, the resist layer 107 remains with a reduced thickness or disappears. In the step S2 of FIG. 1, it is described that the pattern of the resist layers 107 disappears after dry etching. Examples of the fluorine-based gases used for dry etching of the underlayer film 105 include CF₄, CH₃F, CH₂F₂, CHF₃, C₃F₆, C₄F₆, and C₄F₈ and the like, but are not limited to these.

### [Third Step]

Next, dry etching of the organic layer 103 is performed through the pattern of the underlayer film 105 to obtain a pattern of the organic layer 103 (step S3). In the third step, dry etching of the organic layer 103 can be performed with oxygen-based gases. The pattern of the underlayer film 105 serves as a protective film, and after dry etching, the underlayer film 105 remains with a reduced thickness or disappears. In the step S3 of FIG. 1, it is described that the pattern of the underlayer film 105 disappears after dry etching. Examples of the oxygen-based gases used for dry etching of the organic layer 103 include O₂, CO, and CO₂ and the like, but are not limited to these.

### [Fourth Step]

Next, dry etching of the substrate 101 is performed through the pattern of the organic layer 103 to obtain a pattern of the substrate 101 (step S4). In the fourth step, dry etching of the substrate can be performed with the fluorine-based gas or a chlorine-based gas. The pattern of the organic film 103 serves as a protective film, and after dry etching, the thickness is reduced or almost disappears. In step S4 of FIG. 1, it is described that the pattern of the organic film 103 remains after dry etching. Examples of the fluorine-based gas or the chlorine-based gas used for dry etching the substrate 101 include CF₄, CH₃F, CH₂F₂, CHF₃, C₃Fe, C₄F₆, C₄F₈, chlorine trifluoride, chlorine, trichloroborane, dichloroborane, and the like, but are not limited to these.

### [Fifth Step]

After the pattern is formed, the organic layer 103 is removed (if the resist layer 107 and the underlayer film 105 remain, they are also removed), so that the substrate 150 having a desired pattern can be obtained (step S5).

As described above, since the substrate 100 having multiple layers has the underlayer film 105 formed of the resin composition which is a homogeneous solution containing a metal species with high EUV absorbance directly below the resist layer 107, the secondary from EUV photons electrons return from the underlayer film 105 to the resist layer 107 side, EUV photosensitivity increases, and it is possible to obtain the substrate 150 having a fine pattern.

### [Photosensitive Resin Composition]

In an embodiment, the present resin composition can also be used as a photosensitive resin composition. In this case, the photosensitive resin composition further includes (D) a photoinduced compound in addition to the resin composition.

### [(D) Photoinduced Compound]

Examples of (D) the photoinduced compound include, but are not limited to, at least one selected from a group consisting of naphthoquinonediazide, photoacid generator, photobase generator, and photoradical generator.

When exposed to light, the quinonediazide compound releases nitrogen molecules and decomposes to generate a carboxylic acid group in the molecule, thereby improving the solubility of the photosensitive application film obtained from the photosensitive application liquid described above in an alkaline developer. In addition, the alkali solubility of the photosensitive application film in the unexposed portion is suppressed. Therefore, the photosensitive application film containing the quinonediazide compound has a contrast of solubility in the alkali developer at the unexposed and exposed portions, so that a positive pattern can be formed.

For example, the quinonediazide compound is a compound having a quinonediazide group, such as 1,2-quinonediazide group. Examples of the 1,2-quinonediazide compound include 1,2-naphthoquinone-2-diazide-4-sulfonic acid, 1,2-naphthoquinone-2-diazide-5-sulfonic acid, 1,2-naphthoquinone-2-diazide-4-sulfonyl chloride, and 1,2-naphthoquinone-2-diazide-5-sulfonyl chloride. Using the quinonediazide compound makes it possible to obtain a positive photosensitive application film that is sensitive to an i-line (wavelength 365 nm), an h-line (wavelength 405 nm), and a g-line (436 nm) of a mercury lamp, which are common ultraviolet rays.

Examples of a commercially available quinonediazide compound include NT series, 4NT series, and PC-5, manufactured by Toyo Gosei Co., Ltd., TKF series and PQ-C manufactured by SANBO CHEMICAL IND. CO., LTD.

The blending amount of the quinonediazide compound as (D) the photoinduced compound in the photosensitive resin composition is not necessarily limited, but is preferably 1 part by mass or more and 30 parts by mass or less, and more preferably 5 parts by mass or more and 20 parts by mass or less, for example, when (A) or (a) is 100 parts by mass. Using an appropriate amount of the quinonediazide compound makes it easy to achieve both sufficient patterning performance and optical properties such as transparency and refractive index of the obtained patterned cured film.

The photoacid generator will be described. The photoacid generator is a compound that generates an acid upon irradiation with light, and the acid generated at the exposed portion promotes the silanol condensation reaction, that is, the sol-gel polymerization reaction, and the dissolution rate by the alkali developer is remarkably lowered, that is, resistance to the alkali developer can be realized. In addition, in the case where an epoxy group or oxetane group is included in (A) or (a), it is preferable to accelerate each curing reaction. On the other hand, the unexposed portion is dissolved by the alkaline developer without causing this action, and a negative pattern corresponding to the shape of the exposed portion is formed.

Specific examples of the photoacid generator include sulfonium salts, iodonium salts, sulfonyldiazomethanes, N-sulfonyloxyimides, and oxime-O-sulfonates. These photoacid generators may be used alone or in a mixture of two or more thereof. Specific examples of the commercially available product include, but are not limited to, product name: Irgacure 290, Irgacure PAG121, Irgacure PAG103, Irgacure CGI1380, Irgacure CGI725 (manufactured by BASF, USA), product name: PAI-101, PAI-106, NAI-105, NAI-106, TAZ-110, TAZ-204 (manufactured by Midori Kagaku Co., Ltd.), product name: CPI-200K, CPI-210S, CPI-101A, CPI-110A, CPI-100P, CPI-110P, CPI-310B, CPI-100TF, CPI-110TF, HS-1, HS-1A, HS-1P, HS-1N, HS-1TF, HS-1NF, HS-1MS, HS-1CS, LW-S1, LW-S1NF (manufactured by San-Apro Ltd.), product name: TFE-triazine, TME-triazine, or MP-triazine (manufactured by SANWA CHEMICAL CO., LTD.).

The blending amount of the photoacid generator as (D) the photoinduced compound in the photosensitive resin composition is not necessarily limited, but is preferably, for example, 0.01 parts by mass or more and 10 parts by mass or less, and more preferably 0.05 parts by mass or more and 5 parts by mass or less, when (A) or (a) is as 100 parts by mass. Using an appropriate amount of the photoacid generator makes it easy to achieve both sufficient patterning performance and storage stability of the composition.

Next, the photobase generator will be described. The photobase generator is a compound that generates a base (anion) upon irradiation with light, and the base generated at the exposed portion causes the sol-gel reaction to proceed, so that the dissolution rate by the alkali developer is remarkably lowered, that is, resistance to the alkali developer can be realized. On the other hand, the unexposed portion is dissolved by the alkaline developer without causing this action, and a negative pattern corresponding to the shape of the exposed portion is formed.

Specific examples of the photobase generator include amides, amine salts, and the like. Specific examples of the commercially available product include, but are not limited to, product name: WPBG-165, WPBG-018, WPBG-140, WPBG-027, WPBG-266, WPBG-300, WPBG-345 (manufactured by FUJIFILM Wako Pure Chemical Corporation), 2-(9-Oxoxanthen-2-yl)propionic Acid 1,5,7-Triazabicyclo[4.4.0]dec-5-ene Salt, 2-(9-Oxoxanthen-2-yl)propionic Acid, Acetophenone O-Benzoyloxime, 2-Nitrobenzyl Cyclohexylcarbamate, 1,2-Bis(4-methoxyphenyl)-2-oxoethyl Cyclohexylcarbamate (manufactured by Tokyo Chemical Industry Co., Ltd.), and product name: EIPBG, EITMG, EINAP, NMBC (manufactured by EIWEISS Chemical Corporation).

These photoacid generators and photobase generators may be used alone or in combination with two or more kinds or in combination with other compounds.

Specific examples of the combination with other compounds include combinations with amines such as 4,4′-bis(dimethylamino)benzophenone, 4,4′-bis(diethylamino)benzophenone, diethanolmethylamine, dimethylethanolamine, triethanolamine, ethyl-4-dimethylaminobenzoate, and 2-ethylhexyl-4-dimethylaminobenzoate, and combinations of these with iodonium salts such as diphenyliodonium chloride, combinations with dyes such as methylene blue, and amines.

The blending amount of the photobase generator as (D) the photoinduced compound in the photosensitive resin composition is not necessarily limited, but is preferably, for example, 0.01 parts by mass or more and 10 parts by mass or less, and more preferably 0.05 parts by mass or more and 5 parts by mass or less, when (A) or (a) is 100 parts by mass. Using the photobase generator in the amounts indicated here makes it possible to balance the chemical solution resistance of the resulting patterned cured film and the storage stability of the composition.

In addition, the photosensitive resin composition may further contain a sensitizer. Containing the sensitizer promotes the reaction of (D) the photoinduced compound in the exposure process, and the sensitivity and the pattern resolution are improved.

The sensitizer is not particularly limited, but preferably a sensitizer which is vaporized by a heat treatment or a sensitizer which is bleached by light irradiation is used. The sensitizer needs to have light absorption with respect to exposure wavelengths (for example, 365 nm (i-line), 405 nm (h-line), or 436 nm (g-line)) in the exposure process, but if the sensitizer remains in the patterned cured film as it is, absorption is present in the visible-light area, and thus the transparency is lowered. Therefore, in order to prevent a decrease in transparency caused by the sensitizer, the sensitizer used is preferably a compound which is vaporized by a heat treatment such as thermal curing, or a compound which is bleached by light irradiation such as bleaching exposure described later.

Specific examples of the sensitizer vaporized by the above heat treatment and the sensitizer bleached by light irradiation include coumarin such as 3,3′-carbonylbis(diethylaminocoumarin), anthraquinone such as 9,10-anthraquinone, aromatic ketones such as benzophenone, 4,4′-dimethoxybenzophenone, acetophenone, 4-methoxyacetophenone, benzaldehyde, and condensed aromatics such as biphenyl, 1,4-dimethylnaphthalene, 9-fluorenone, fluorene, phenanthrene, triphenylene, pyrene, anthracene, 9-phenylanthracene, 9-methoxyanthracene, 9,10-diphenylanthracene, 9,10-bis(4-methoxyphenyl)anthracene, 9,10-bis(triphenylsilyl)anthracene, 9,10-dimethoxyanthracene, 9,10-diethoxyanthracene, 9,10-dipropoxyanthracene, 9,10-dibutoxyanthracene, 9,10-dipentaoxyanthracene, 2-t-butyl-9,10-dibutoxyanthracene, and 9,10-bis(trimethylsilylethynyl)anthracene. Examples of commercially available materials include ANTHRACURE (manufactured by Kawasaki Kasei Chemicals Ltd.).

In the case where these sensitizers are added, the blending amount thereof is preferably 0.001 parts by mass or more and 10 parts by mass or less with respect to 100 parts by mass of (A) or (a).

In addition, whether the sensitizers described above are used alone or in a mixture of two or more thereof may be appropriately determined by a person skilled in the art depending on the application, usage environment, and restriction.

### [Patterning Method Using Photosensitive Resin Composition]

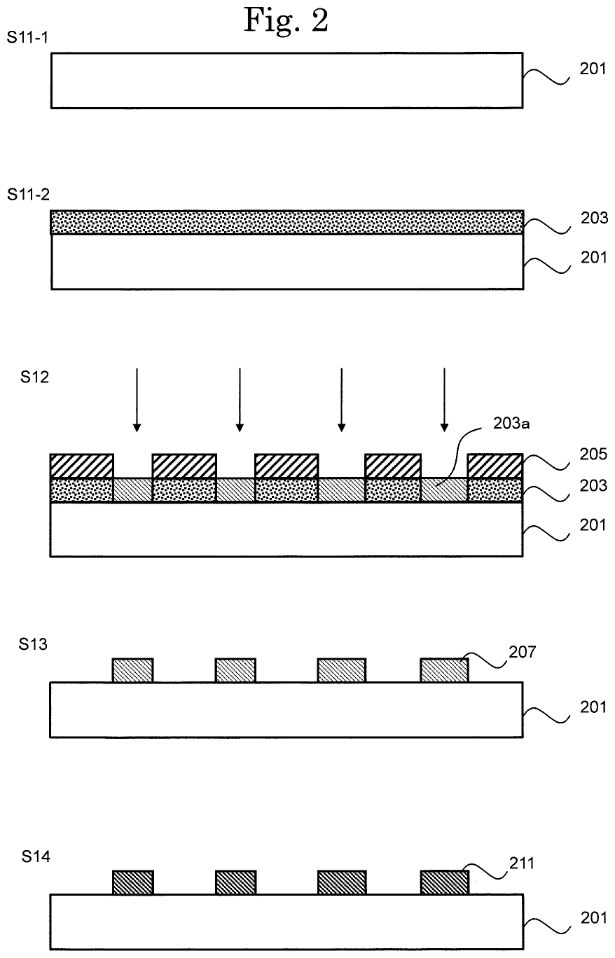

Next, a patterning method using the photosensitive resin composition (also referred to as a “method for producing a patterned cured film” in the present specification) will be described. FIG. 2 is a schematic diagram illustrating a method of producing a negative patterned cured film 211 according to an embodiment of the present invention. The present invention can also produce a positive patterned cured film 211.

The present photosensitive resin composition can also be used for the production of the substrate 150 having a pattern shown in FIG. 1. In this case, the resist layer 107 is not required, and multiple layers composed of only two layers of the underlayer film 105 and the organic film 103 can be used, which contributes to a significant reduction in the number of steps, and the photosensitive resin composition is very useful.

The “patterned cured film” in the present specification is a cured film that is developed after the exposure step to form a pattern, and the obtained pattern is cured as described below.

The method for producing the patterned cured film 211 can include the following first to fourth steps.

First step: applying the photosensitive application liquid on a substrate 201 and heating the application liquid to form a photosensitive application film 203.

Second step: exposing the photosensitive application film 203 via a light-shielding plate (photomask) 205.

Third step: developing the exposed photosensitive application film 203 to form a patterned film 207.

Fourth step: heating the patterned film 207, thereby curing the patterned film 207 and converting it into the patterned cured film 211.

### [First Step]

The substrate 201 is prepared (step S11-1). The substrate 201 to which the photosensitive resin composition is applied is selected from a silicon wafer, a metal, a glass, a ceramic, and a plastic substrate depending on the application of the patterned cured film to be formed. Specific examples of the substrate used in a semiconductor or a display include silicon, silicon nitride, glass, polyimide (Kapton), polyethylene terephthalate, polycarbonate, polyethylene naphthalate, and the like. In addition, the substrate 201 may have any layer such as silicon, metal, glass, ceramic, or resin on the surface thereof, and “on the substrate” may be a surface of the substrate or via the layer.

A known coating method such as spin coating, dip coating, spray coating, bar coating, applicator, ink jet or roll coater can be used as a coating method on the substrate 201 without any particular limitation.

Thereafter, the substrate 201 coated with the present photosensitive resin composition is heated, whereby the photosensitive application film 203 can be obtained (step S11-2). In the heat treatment, the solvent may be removed to such an extent that the obtained photosensitive application film 203 does not easily flow or deform, and it may be heated under conditions of, for example, 80° C. to 120° C. for 30 seconds or more and 5 minutes or less.

### [Second Step]

Next, the photosensitive application film 203 obtained in the first step is shielded by the light-shielding plate (photomask) 205 having a desired shape for forming a desired pattern, and then the photosensitive application film 203 is irradiated with light and subjected to the exposure process to obtain the exposed photosensitive application film 203 (step S12). The exposed photosensitive application film 203 includes an exposed portion 203a and an unexposed portion.

A known method can be used for the exposure process. A light beam having wavelengths in the range of 1 nm to 600 nm can be used as a light source. Specifically, for example, a low-pressure mercury lamp, a high-pressure mercury lamp, an ultra-high-pressure mercury lamp, a KrF excimer laser (wavelength 248 nm), an ArF excimer laser (wavelength 193 nm), or an EUV beam (wavelength 6 nm to 27 nm, preferably 13.5 nm), or the like can be used. The exposure amount can be adjusted according to the type and amount of the photoinduced compound to be used, the producing process, and the like, and is not particularly limited, but may be about 1 to 10,000 mJ/cm², preferably about 10 to 5,000 m J/cm².

After the exposure, post-exposure heating may be performed before the development step, if necessary. The temperature of the post-exposure heating is preferably 60° C. to 180° C., and the time of the post-exposure heating is preferably 30 seconds to 10 minutes.

### [Third Step]

Next, developing the exposed photosensitive application film 203 obtained in the second step removes the portions other than the exposed portion 203a, and a film having a desired pattern (hereinafter, sometimes referred to as the “patterned film”) 207 can be formed (step S13). Although FIG. 2 is a diagram illustrating the method of manufacturing the negative patterned cured film, in the case where the positive patterned cured film is obtained, the exposed portion 203a is removed by developing, and the photosensitive application film 203, which is an unexposed portion shielded by the light-shielding plate 205, becomes the patterned film 207. The photoacid generator is used as (D) the photoinduced compound, and the negative patterned cured film is obtained when X is a hydrogen atom, and the positive patterned cured film is obtained when X is an acid-labile group.

Development means to form a pattern by dissolving and washing and removing an unexposed portions or exposed portions using an alkaline solution as a developer.

The developer to be used is not particularly limited as long as it can remove a desired photosensitive application film by a predetermined development method. Specific examples include alkali aqueous solutions using inorganic alkalis, primary amines, secondary amines, tertiary amines, alcohol amines, quaternary ammonium salts, and mixtures thereof.

More specific examples include an alkaline aqueous solution such as potassium hydroxide, sodium hydroxide, ammonia, ethylamine, diethylamine, triethylamine, triethanolamine, and tetramethylammonium hydroxide (abbreviation: TMAH). Among them, TMAH aqueous solution is preferably used, and in particular, TMAH aqueous solution of 0.1% by mass or more and 5% by mass or less, more preferably 2% by mass or more and 3% by mass or less is preferably used.

A known method such as an immersion method, a paddle method, or a spray method can be used as the development method, and the development time may be 0.1 minutes or more and 3 minutes or less. In addition, it is preferably 0.5 minutes or more and 2 minutes or less. Thereafter, the desired patterned film 207 can be formed on the substrate 201 by washing, rinsing, drying, or the like as necessary.

In addition, a bleaching exposure is preferably performed after forming the patterned film 207. The purpose of the bleaching exposure is to improve the transparency of the finally obtained patterned cured film 211 by photolyzing the photoinduced compound remaining in the patterned film 207. The bleaching exposure can be performed in the same manner as in the second step.

### [Fourth Step]

Next, the patterned film (including the bleached-exposed patterned film) 207 obtained in the third step is subjected to a heat treatment to obtain the final patterned cured film 211 (step S14). The heat treatment makes it possible to condense the alkoxy group or the silanol group remaining as unreacted groups in (A) or (a). In addition, it is possible to remove the photoinduced compound or photodegradation products of the photoinduced compound by thermal decomposition.

The heating temperature at this time is preferably 80° C. or more and 400° C. or less, and more preferably 100° C. or more and 350° C. or less. The heat treatment time may be 1 minute or more and 90 minutes or less, preferably 5 minutes or more and 60 minutes or less. Setting the heating temperature within the above range sufficiently proceeds the condensation reaction, the curing reaction, the thermal decomposition of the photoinduced compound or the photodegradation product of the photoinduced compound, and the desired chemical solution resistance, heat resistance, and transparency can be obtained. In addition, it is possible to suppress thermal decomposition of the components constituting the patterned cured film 211 and cracks of the film to be formed, and it is possible to obtain a film having good adhesion to the substrate 201. The desired patterned cured film 211 can be formed on the substrate 201 by the heat treatment.

### EXAMPLES

Hereinafter, although the present invention will be described in more detail with reference to examples, the present invention is not limited to the following examples unless the gist thereof is exceeded.

In the examples, unless otherwise indicated, some compounds are designated as follows.
Ph-Si: phenyltriethoxysilane
PGMEA: Propylene glycol monomethyl ether acetate
HFA-Si: a compound represented by the following chemical formula:

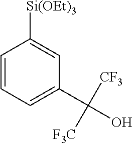

HFA-PH-MES: a compound represented by the following chemical formula:

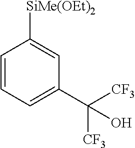

Equipment used for various measurements and measurement conditions will be described.

### [Weight Average Molecular Weight Measurement]

The weight average molecular weight (Mw) of the resin composition or the like described below was measured as follows. A high-speed GPC device manufactured by Tosoh Corporation, device name: HLC-8320GPC, TSKgel SuperHZ2000 manufactured by Tosoh Corporation as a column, and tetrahydrofuran (THF) as a solvent were used and measured in terms of polystyrene.

### Synthesis Example 1: Synthesis of HFA-Si

HFA-Si was synthesized in a known method according to International patent publication No. 2019/167770.

### Synthesis Example 2: Synthesis of HFA-PH-MES

HFA-PH-MES was synthesized in a known method according to International patent publication No. 2019/167770.

### Example 1

3.25 g (8 mmol) of HFA-Si, 2.02 g (8 mmol) of germanium tetraethoxide, and 0.19 g (3.2 mmol) of acetic acid were added to the reaction vessel, and the mixture was stirred at room temperature for 24 hours, then 3.68 g of ethanol was added and stirred for 5 minutes, and then 0.14 g (8 mmol) of pure water was added to the reaction vessel to confirm that a homogeneous solution was maintained without change before the pure water was added. 0.29 g (3.2 mmol) of 69% nitric acid was then added and stirred for an additional 24 hours. The reaction solution finally obtained was also a homogeneous solution. 20 g of PGMEA was then added and treated with an evaporator at 50° C. to obtain 18 g of a homogeneous solution (solution 1). The weight average molecular weight Mw determined by GPC measurement was 1,890. (A), (B), and (C) of the solution 1 are described in Table 1.

### Comparative Example 1

1.92 g (8 mmol) of Ph-Si, 2.02 g (8 mmol) of germanium tetraethoxide, and 0.19 g (3.2 mmol) of acetic acid were added to the reaction vessel, and the mixture was stirred at room temperature for 24 hours, 3.68 g of ethanol was added and stirred for 5 minutes, and 0.14 g (8 mmol) of pure water was added to produce a white precipitate.

### Example 2

1.92 g (4.7 mmol) of HFA-Si, 1.19 g (4.7 mmol) of germanium tetraethoxide, and 3.0 g of ethanol were added to the reaction vessel, and the mixture was stirred at 70° C., and then a mixed solution of 12 g of ethanol, 0.24 g of pure water, and 0.05 g (0.5 mmol) of maleic acid were added dropwise and stirred for an additional 3 hours. The reaction solution finally obtained was also a homogeneous solution. 20 g of PGMEA was then added and treated with an evaporator at 50° C. to obtain 18 g of a homogeneous solution (solution 2). The weight average molecular weight Mw determined by GPC measurement was 1,660. (A), (B), and (C) of the solution 2 are described in Table 1.

### Comparative Example 2

1.92 g (4.7 mmol) of Ph-Si, 1.19 g (4.7 mmol) of germanium tetraethoxide, and 3.0 g of ethanol were added to the reaction vessel, and the mixture was stirred at 70° C. and then mixed solutions of 12 g of ethanol, 0.24 g of pure water, and 0.05 g (0.5 mmol) of maleic acid were added dropwise to produce a white precipitate.

From the results of Examples 1 and 2 and Comparative Examples 1 and 2, although the details are unknown, it is considered that the HFIP group enhances the compatibility with germanium tetraethoxide at the time of hydrolysis and polycondensation.

### Example 3

1.92 g (4.7 mmol) of HFA-Si, 2.39 g (9.45 mmol) of germanium tetraethoxide, 1.97 g (9.45 mmol) of tetraethoxysilane, and 6.0 g of ethanol were added to the reaction vessel, and the mixture was stirred at 70° C., and then a mixed solution of 18 g of ethanol, 0.48 g of pure water, and 0.14 g (1.2 mmol) of maleic acid were added dropwise and stirred for an additional 3 hours. The reaction solution finally obtained was also a homogeneous solution. 20 g of PGMEA was then added and treated with an evaporator at 50° C. to obtain 20 g of a homogeneous solution (solution 3). The weight average molecular weight Mw determined by GPC measurement was 6,500. (A), (B), and (C) of the solution 3 are described in Table 1.

### Example 4

1.30 g (3.2 mmol) of HFA-Si, 1.33 g (6.4 mmol) of tetraethoxysilane, 1.15 g of pure water, 2.24 g (6.4 mmol) of tin (IV) chloride pentahydrate, and 15 g of ethanol were added to the reaction vessel, and the mixture was stirred at room temperature to confirm that the mixture became a homogeneous solution. Thereafter, the mixture was stirred at 80° C. for 4 hours, and the reaction solution finally obtained was also a homogeneous solution. 20 g of PGMEA was then added and treated with an evaporator at 50° C. to obtain 21 g of a homogeneous solution (solution 4). The weight average molecular weight Mw determined by GPC measurement was 1,800. (A), (B), and (C) of the solution 4 are described in Table 1.

### Comparative Example 3

0.77 g (3.2 mmol) of Ph-Si, 1.33 g (6.4 mmol) of tetraethoxysilane, 1.15 g of pure water, 2.24 g (6.4 mmol) of tin (IV) chloride pentahydrate, and 15 g of ethanol were added to the reaction vessel, and the mixture was stirred at room temperature, and it gelled and precipitated.

### Example 5

4.27 g (1.9 mmol) of HFA-Si, 9.45 g (2.4 mmol) of germanium tetraethoxide, 9.45 g (3.6 mmol) of HFA-PH-MES, and 6.0 g of ethanol were added to the reaction vessel, and the mixture was stirred at 70° C., and then a mixed solution of 18 g of ethanol, 0.5 g of pure water, and 0.14 g (1.2 mmol) of maleic acid were added dropwise and stirred for an additional 24 hours. The reaction solution finally obtained was also a homogeneous solution. 20 g of PGMEA was then added and treated with an evaporator at 50° C. to obtain 20 g of a homogeneous solution (solution 5). The weight average molecular weight Mw determined by GPC measurement was 6,700. (A), (B), and (C) of the solution 5 are described in Tables 1 to 2.

TABLE 1

| | Liquid property | (A) | (B) | (C) |
|---|---|---|---|---|
| Example | Homogeneous | R² is represented by | R¹ is a hydroxyl | PGMEA |
| 1 | solution | the general formula | group or ethoxy | |
| | (solution 1) | (1aa), | group, or a | |
| | | X is a hydrogen atom | combination | |
| | | R⁴ is a hydrogen atom | thereof | |
| | | or ethyl group, or a | M is Ge | |
| | | combination thereof | b is a number of | |
| | | d is 1 | 0 or more and 3 | |
| | | e is 0 | or less | |
| | | f is a number of 0 or | c is a number of | |
| | | more and less than 3 | 1 or more and 4 | |
| | | g is a number more | or less | |
| | | than 0 and 3 or less | b + c is 4 | |
| | | d + e + f + g is 4 | | |
| Example | Homogeneous | R² is represented by | R¹ is a hydroxyl | PGMEA |
| 2 | solution | the general formula | group or an | |
| | (solution 2) | (1aa), | ethoxy group, or | |
| | | X is a hydrogen atom | a combination | |
| | | R⁴ is a hydrogen atom | thereof | |
| | | or ethyl group, or a | M is Ge | |
| | | combination thereof. | b is a number of | |
| | | d is 1 | 0 or more and 3 | |
| | | e is 0 | or less | |
| | | f is a number of 0 or | c is a number of | |
| | | more and less than 3 | 1 or more and 4 | |
| | | g is a number more | or less | |
| | | than 0 and 3 or less | b + c is 4 | |
| | | d + e + f + g is 4 | | |
| Example | Homogeneous | R² is represented by | R¹ may be a | PGMEA |
| 3 | solution | the general formula | hydroxyl group | |
| | (solution 3) | (1aa), | or an ethoxy | |
| | | X is a hydrogen atom | group, or a | |
| | | R⁴ is a hydrogen atom | combination | |
| | | or ethyl group, or a | thereof | |
| | | combination thereof | M is Ge | |
| | | d is more than 0 and | b is a number of | |
| | | less than 1 | 0 or more and 3 | |
| | | e is 0 | or less | |
| | | f is a number of 0 or | c is a number of | |
| | | more and less than 4 | 1 or more and 4 | |
| | | g is a number more | or less | |
| | | than 0 and less than 4 | b + c is 4 | |
| | | d + e + f + g is 4 | | |
| | | R⁷ is a hydroxyl group | | |
| | | or ethoxy group, or a | | |
| | | combination thereof | | |
| | | k is a number of 0 or | | |
| | | more and 3 or less | | |
| | | l is a number of 1 or | | |
| | | more and 4 or less | | |
| | | k + l is 4 | | |

TABLE 2

| | | | | |
|---|---|---|---|---|
| Example | Homogeneous | R² is represented by | R¹ is a hydroxyl | PGMEA |
| 4 | solution | the general formula | group or | |
| | (solution 4) | (1aa), | chlorine group, | |
| | | X is a hydrogen atom | or a | |
| | | R⁴ is a hydrogen atom | combination | |
| | | or ethyl group, or a | thereof | |
| | | combination thereof. | M is Sn | |
| | | d is more than 0 and | b is a number of | |
| | | less than 1 | 0 or more and 3 | |
| | | e is 0 | or less | |
| | | f is a number of 0 or | c is a number of | |
| | | more and less than 4 | 1 or more and 4 | |
| | | g is a number more | or less | |
| | | than 0 and less than 4 | b + c is 4 | |
| | | d + e + f + g is 4 | | |
| | | R⁷ is a hydroxyl group | | |
| | | or ethoxy group, or a | | |
| | | combination thereof | | |
| | | k is a number of 0 or | | |
| | | more and 3 or less | | |
| | | l is a number of 1 or | | |
| | | more and 4 or less | | |
| | | k + l is 4 | | |
| Example | Homogeneous | R² is represented by | R¹ is a hydroxyl | PGMEA |
| 5 | solution | the general formula | group or ethoxy | |
| | (solution 5) | (1aa), | group, or a | |
| | | X is a hydrogen atom | combination | |
| | | R⁴ represents a | thereof | |
| | | hydrogen atom or | M is Ge | |
| | | ethyl group, or a | b is a number of | |
| | | combination thereof | 0 or more and 3 | |
| | | R³ is a methyl group | or less | |
| | | d is 1 | c is a number of | |
| | | e is a number more | 1 or more and 4 | |
| | | than 0 and of 3 or less | or less | |
| | | f is a number of 0 or | b + c is 4 | |
| | | more and less than 3 | | |
| | | g is a number more | | |
| | | than 0 and of 3 or less | | |
| | | d + e + f + g is 4 | | |

### Comparative Example 4

Polysiloxane composed of HFA-Si and silicate 40 (pentamer on average, manufactured by TAMA CHEMICALS CO., LTD.) were synthesized by the method described in International patent publication No. 2019/167771. The weight average molecular weight Mw determined by GPC measurement was 1,860. 1 g of the obtained polysiloxane was dissolved in 10 g of PGMEA to obtain a solution 6.

### [Evaluation of Etching Rate and Etching Selectivity]

The solution 2 obtained in Example 2 described above, the solution 3 obtained in Example 3, and the solution 6 obtained in Comparative Example 4 were filtered through a filter with a pore size of 0.22 μm, and spin-coated on a 4-inch-diameter 525-μm-thick silicon wafer manufactured by SUMCO CORPORATION at a rotational rate of 500 rpm, and then the silicon wafer was baked on a hot plate at 200° C. for 3 minutes. In this way, cured films 2-1, 3-1, and 4-1 having thicknesses of 0.4 μm to 0.6 μm were formed on the silicon wafer. As a result of measuring the obtained cured film by X-ray photoelectron spectroscopy, the total content of M atoms in the general formula (1-A) was as follows: the cured film 2-1 was 15 atm %, the cured film 3-1 was 9 atm %, and the cured film 4-1 was 4.1 atm %. In the same manner as described above, cured films 1-1 and 5-1 were formed on the silicon wafer using the solution 1 obtained in Example 1 and the solution 5 obtained in Example 5, respectively, and the cured films were measured by X-ray photoelectron spectroscopy, and as a result, the total content of M atoms in the general formula (1-A) was as follows: the cured film 1-1 was 14 atm % and the cured film 5-1 was 3.1 atm %.

The obtained cured film on the silicon wafer was dry-etched with a fluorine-based gas (CF₄ and CHF₃) and an oxygen-based gas (CO₂ or O₂), and the etching rate with respect to each gas was measured to calculate the etching selectivity. Etching conditions (1) to (3) are shown below (hereinafter, the etching rate may be simply referred to as a rate, and the etching condition may be simply referred to as a condition).

[Condition (1)] Use of CF₄ and CHF₃ as fluorine-based gas
CF₄ flow rate: 150 sccm
CHF₃ flow rate: 50 sccm
Ar flow rate: 100 sccm
Chamber pressure: 10 Pa
Applied power: 400 W
Temperature: 15° C.
   [Condition (2)] Use of CO₂ as oxygen-based gas
CO₂ flow rate: 300 sccm
Ar flow rate: 100 sccm
N₂ flow rate: 100 sccm
Chamber pressure: 2 Pa
Applied power: 400 W
Temperature: 15° C.
   [Condition (3)] Use of O₂ as oxygen-based gas
O₂ flow rate: 400 sccm
Ar flow rate: 100 sccm
Chamber pressure: 2 Pa
Applied power: 400 W
Temperature: 15° C.

Measurement values of the etching rate under the etching conditions (1) to (3) and the etching rate ratio obtained therefrom are shown in Table 3. An etching rate ratio A is a value obtained by dividing the measured value of the speed according to the condition (1) by the measured value of the speed according to the condition (2), and an etching rate ratio B is a value obtained by dividing the measured value of the speed according to the condition (1) by the measured value of the speed according to the condition (3).

TABLE 3

| | Etching Rate Measurement | | | | |
|---|---|---|---|---|---|
| | (nm/min) | | | | |
| | Condi- | Condi- | Condi- | Etching selectivity | |
| | tion (1) | tion (2) | tion (3) | Rate | Rate |
| | CF₄ + CHF₃ | CO₂ | O₂ | ratio A | ratio B |
| Cured film 2-1 | 98 | 1 | 1.4 | 98 | 70 |
| Cured film 3-1 | 104 | 0.7 | 1 | 146 | 104 |
| Cured film 4-1 | 91 | 2 | 5 | 46 | 12 |

As shown in Table 3, the cured film 2-1 obtained from the solution 2 obtained in Example 2 and the cured film 3-1 obtained from the solution 3 obtained in Example 3 had a larger fluorine etching rate value than the cured film 4-1 obtained from the solution 6 obtained in Comparative Example 4, and was excellent in 02 plasma etching resistance (the etching rate values of Condition (2) and Condition (3) were small), and was excellent in the etching selectivity of the fluorine-based gas and the oxygen-based gas (both the rate ratio A and the rate ratio B of the etching selectivity were large).

According to an embodiment of the present invention, the present invention provides a resin composition, which is a homogeneous solution containing a polymer, obtained by hydrolysis and polycondensation without precipitation of the raw material-derived components during the sol-gel reaction even when a metal species with high EUV absorbance is introduced.

Alternatively, the present invention provides a resin composition, which is a homogeneous solution containing a mixture without precipitation in a blend even when a metal species with high EUV absorbance is used.

Alternatively, the present invention provides a cured film of a resin composition or a method for producing the same.

Alternatively, the present invention provides a substrate having multiple layers having an underlayer film of a resist which is a cured film of a resin composition or a method for producing a substrate having a pattern using the substrate having multiple layers.

Alternatively, the present invention provides a method for producing a photosensitive resin composition containing a resin composition and a method for producing a patterned cured film formed by coating the photosensitive resin composition onto a substrate.

Alternatively, the present invention provides a method for producing a polymer obtained by hydrolysis and polycondensation without precipitation of components derived from a raw material during the sol-gel reaction even when a metal species with high EUV absorbance is introduced.

Alternatively, the present invention provides a method for producing a resin composition for treating the obtained polymer.

What is claimed is:

1. A resin composition comprising:
a polymer including:
(A) a constituent unit represented by a following general formula (1);
(B) a constituent unit represented by a following general formula (1-A);
[(R²)_{d}(R³)ₑ(OR⁴)_{f}SiO_{g/2}] (1)
[(R¹)_{b}MO_{c/2}] (1-A)
wherein, in the general formula (1-A), M is at least one selected from a group consisting of Fe, Co, Ni, Cu, Zn, Ga, Ge, Mo, Pd, Ag, Sn, Cs, Ba, W, and Hf, each R¹ is independently selected from a group consisting of a hydrogen atom, hydroxy group, halogen group, an alkoxy group having a carbon number of 1 or more and 5 or less, an alkyl group having a carbon number of 1 or more and 5 or less, a phenyl group, and a fluoroalkyl group having a carbon number of 1 or more and 10 or less,
b is a number of 0 or more and less than 4, c is a number more than 0 and 4 or less, and b+c=3 or 4,
in the general formula (1), R² is a group represented by a following general formula (1a), 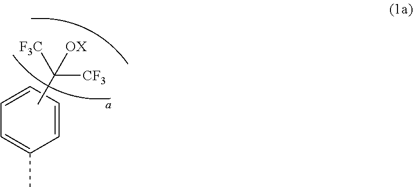
in the general formula (1a), X is a hydrogen atom or an acid-labile group,
a is a number of 1 to 5, and a broken line represents a bond,
each R³ is independently selected from a group consisting of a hydrogen atom, an alkyl group having a carbon number of 1 or more and 5 or less, a phenyl group, and a fluoroalkyl group having a carbon number of 1 or more and 10 or less, and each R⁴ is independently a hydrogen atom or an alkyl group having a carbon number of 1 or more and 5 or less,
d is a number of 1 or more and 3 or less, e is a number of 0 or more and 2 or less, f is a number of 0 or more and less than 3, g is a number more than 0 and 3 or less, and d+e+f+g=4.

2. A resin composition comprising:
(a) polysiloxane compound including a constituent unit represented by a following general formula (1); and
(b) metalloxane compound including a constituent unit represented by a following general formula (1-A);
[(R²)_{d}(R³)ₑ(OR⁴)_{f}SiO_{g/2}] (1)
[(R¹)_{b}MO_{c/2}] (1-A)
wherein, in the general formula (1-A), M is at least one selected from a group consisting of Fe, Co, Ni, Cu, Zn, Ga, Ge, Mo, Pd, Ag, Sn, Cs, Ba, W, and Hf,
each R¹ is independently selected from a group consisting of a hydrogen atom, hydroxy group, halogen group, an alkoxy group having a carbon number of 1 or more and 5 or less, an alkyl group having a carbon number of 1 or more and 5 or less, a phenyl group, and a fluoroalkyl group having a carbon number of 1 or more and 10 or less,
b is a number of 0 or more and less than 4, c is a number more than 0 and 4 or less, and b+c=3 or 4,
in the general formula (1), R² is a group represented by a following general formula (1a), 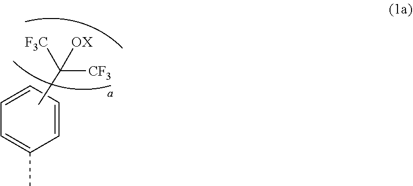
in the general formula (1a), X is a hydrogen atom or an acid-labile group,
a is a number of 1 to 5, and a broken line represents a bond,
each R³ is independently selected from a group consisting of a hydrogen atom, an alkyl group having a carbon number of 1 or more and 5 or less, a phenyl group, and a fluoroalkyl group having a carbon number of 1 or more and 10 or less, and each R⁴ is independently a hydrogen atom or an alkyl group having a carbon number of 1 or more and 5 or less,
d is a number of 1 or more and 3 or less, e is a number of 0 or more and 2 or less, f is a number of 0 or more and less than 3, g is a number more than 0 and 3 or less, and d+e+f+g=4.

3. The resin composition according to claim 1, wherein the group represented by the general formula (1a) is a group represented by any of following general formulas (1aa) to (1ad), 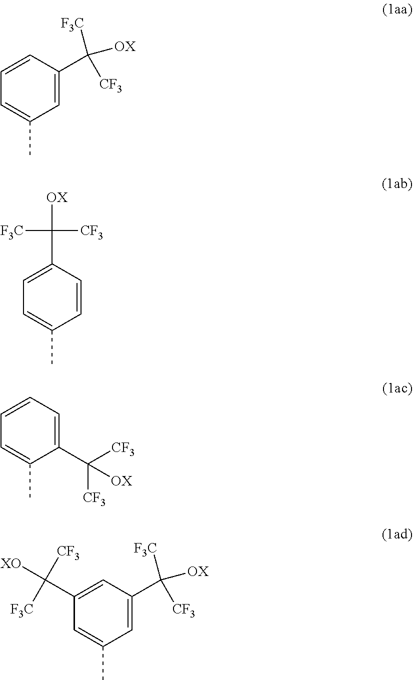
wherein, in the general formulas (1aa) to (1ad), the definitions of X and the broken line are the same as the definitions in the general formula (1a).

4. The resin composition according to claim 1, wherein the polymer further includes:
a constituent unit represented by a following general formula (2) and/or a following general formula (3),
[(R⁵)ₕ(R⁶)ᵢSiO_{j/2}] (2)
[(R⁷)ₖSiO_{l/2}] (3)
wherein, in the general formula (2), R⁵ is a substituent selected from monovalent organic groups having a carbon number of 1 or more and 30 or less substituted by any of an epoxy group, oxetane group, acryloyl group, methacryloyl group, and a lactone group,
R⁶ is a hydrogen atom, or a substituent selected from a group consisting of a halogen group, an alkyl group having a carbon number of 1 or more and 5 or less, a phenyl group, hydroxy group, an alkoxy group having a carbon number of 1 or more and 3 or less, and a fluoroalkyl group having a carbon number of 1 or more and 10 or less,
h is a number of 1 or more and 3 or less, i is a number of 0 or more and less than 3, j is a number more than 0 and 3 or less, and h+i+j=4,
when there is a plurality of R⁵ and R⁶, each of them is independently selected from any of the substituents,
in the general formula (3), R⁷ is a substituent selected from a group consisting of a halogen group, alkoxy group, and hydroxy group, and
k is a number of 0 or more and less than 4, l is a number more than 0 and 4 or less, and k+l=4.

5. The resin composition according to claim 2, wherein at least one of (a) the polysiloxane compound including a constituent unit represented by the general formula (1) and (b) the metalloxane compound including a constituent unit represented by the general formula (1-A) further includes:
a constituent unit represented by a following general formula (2) and/or a following general formula (3),
[(R⁵)ₕ(R⁶)ᵢSiO_{j/2}] (2)
[(R⁷)ₖSiO_{l/2}] (3)
wherein, in the general formula (2), R⁵ is a substituent selected from monovalent organic groups having a carbon number of 1 or more and 30 or less substituted by any of an epoxy group, oxetane group, acryloyl group, methacryloyl group and a lactone group,
R⁶ is a hydrogen atom, or a substituent selected from a group consisting of a halogen group, an alkyl group having a carbon number of 1 or more and 5 or less, a phenyl group, hydroxy group, an alkoxy group having a carbon number of 1 or more and 3 or less, and a fluoroalkyl group having a carbon number of 1 or more and 10 or less,
h is a number of 1 or more and 3 or less, i is a number of 0 or more and less than 3, j is a number more than 0 and 3 or less, and h+i+j=4,
when there is a plurality of R⁵ and R⁶, each of them is independently selected from any of the substituents,
in the general formula (3), R⁷ is a substituent selected from a group consisting of a halogen group, alkoxy group, and hydroxy group, and
k is a number of 0 or more and less than 4, l is a number more than 0 and 4 or less, and k+l=4.

6. The resin composition according to claim 4, wherein the monovalent organic group R⁵ is any substituent represented by following general formulas (2a), (2b), (2c), (3a), and (4a), 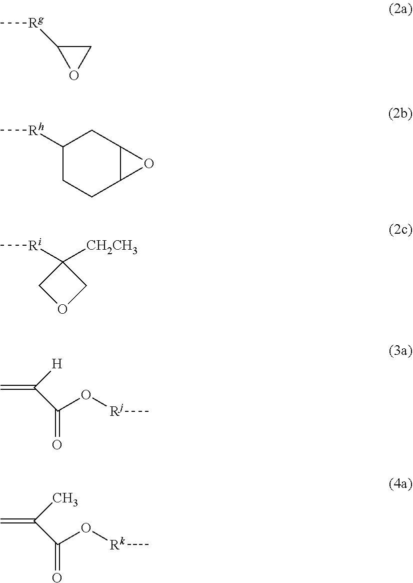
wherein, in the general formulas (2a), (2b), and (2c), each R^{g}, R^{h}, Rⁱ is independently a divalent linking group, and a broken line represents a bond, and
in the general formulas (3a) and (4a), each R^{j} and R^{k} is independently a divalent linking group, and a broken line represents a bond.

7. The resin composition according to claim 1, wherein in the general formula (1-A), M is at least one selected from a group consisting of Ge, Mo, and W.

8. The resin composition according to claim 1, further comprising:
(C) a solvent.

9. The resin composition according to claim 8, wherein (C) the solvent includes at least one compound selected from a group consisting of propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols, glycol ethers, and glycol ether esters.

10. A cured film made of a cured resin composition, wherein the resin composition according to claim 1 is cured.

11. A method for producing a cured film comprising:
a step of applying the resin composition according to claim 1 onto a substrate and heating the resin composition at a temperature of 80° C. or more and 350° C. or less.

12. A substrate having multiple layers comprising:
an organic layer onto a substrate, an underlayer film for a resist, the underlayer film being a cured film wherein the resin composition according to claim 1 is cured; and
a resist layer on the underlayer film.

13. A method for producing a substrate having a pattern comprising:
a first step of exposing the resist layer to the substrate having multiple layers according to claim 12 through a photomask to obtain a pattern by developing the exposed resist layer with a developer;
a second step of dry etching of the underlayer film through the developed pattern of the resist layer to obtain a pattern of the underlayer film;
a third step of dry etching of the organic layer through the pattern of the underlayer film to obtain a pattern of the organic layer; and
a fourth step of dry etching of the substrate through the pattern of the organic layer to obtain a pattern of the substrate.

14. The method for producing the substrate having the pattern according to claim 13, wherein the dry etching of the underlayer film is performed by a fluorine-based gas in the second step,
the dry etching of the organic layer is performed by an oxygen-based gas in the third step, and
the dry etching of the substrate is performed by a fluorine-based gas or a chlorine-based gas in the fourth step.

15. The method for producing the substrate having the pattern according to claim 13, wherein a wavelength of a light beam used in the exposure is 1 nm or more and 600 nm or less.

16. The method for producing the substrate having the pattern according to claim 13, wherein a wavelength of a light beam used in the exposure is 6 nm or more and 27 nm or less.

17. A photosensitive resin composition comprising:
the resin composition according to claim 1; and
(D) a photoinduced compound.

18. A photosensitive resin composition according to claim 17, wherein (D) the photoinduced compound is at least one selected from a group consisting of naphthoquinonediazide, photoacid generator, photobase generator, and photoradical generator.

19. A method for producing a patterned cured film comprising:
a step of applying the photosensitive resin composition according to claim 17 onto a substrate to form a photosensitive application film;
exposing the photosensitive application film through a photomask;
developing the photosensitive application film after exposure to form a patterned film; and
curing the patterned film by heating the patterned film to obtain the patterned cured film.

20. The method for producing the patterned cured film according to claim 19, wherein the photosensitive application film is exposed by irradiating a light beam having a wavelength of 1 nm or more and 600 nm or less through the photomask.

21. A method for producing a polymer comprising:
conducting hydrolysis and polycondensation of a silicon compound represented by a following general formula (1y) and a metal compound represented by a following general formula (1-2),
wherein the polymer includes a constituent unit represented by a following general formula (1); and a constituent unit represented by a following general formula (1-A), 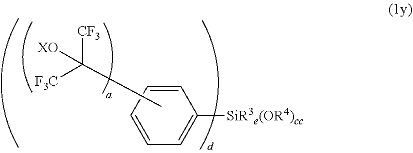
M(R⁸)ₘ(R⁹)ₙ (1-2)
[(R²)_{d}(R³)ₑ(OR⁴)_{f}SiO_{g/2}] (1)
[(R¹)_{b}MO_{c/2}] (1-A)
wherein, in the general formula (1y), each R³ is independently selected from a group consisting of a hydrogen atom, an alkyl group having a carbon number of 1 or more and 5 or less, a phenyl group, and a fluoroalkyl group having a carbon number of 1 or more and 10 or less, R⁴ is independently a hydrogen atom or an alkyl group having a carbon number of 1 or more and 5 or less, a is a number of 1 or more and 5 or less, d is a number of 1 or more and 3 or less, e is a number of 0 or more and 2 or less, cc is a number of 1 or more and less than 4, and d+e+cc=4, X is a hydrogen atom or an acid-labile group,
in the general formula (1-2), M is at least one selected from a group consisting of Fe, Co, Ni, Cu, Zn, Ga, Ge, Mo, Pd, Ag, Sn, Cs, Ba, W, and Hf, each R⁸ is independently selected from a group consisting of a hydrogen atom, hydroxy group, halogen group, an alkoxy group having a carbon number of 1 or more and 5 or less, an alkyl group having a carbon number of 1 or more and 5 or less, a phenyl group, and a fluoroalkyl group having a carbon number of 1 or more and 10 or less, R⁹ is an alkoxy group having a carbon number of 1 or more and 5 or less, or a halogen,
m is a number of 0 or more and 3 or less, n is a number of 1 or more and 4 or less, and m+n=3 or 4,
in the general formula (1-A), M is at least one selected from a group consisting of Fe, Co, Ni, Cu, Zn, Ga, Ge, Mo, Pd, Ag, Sn, Cs, Ba, W, and Hf, each R¹ is independently selected from a group consisting of a hydrogen atom, hydroxy group, halogen group, an alkoxy group having a carbon number of 1 or more and 5 or less, an alkyl group having a carbon number of 1 or more and 5 or less, a phenyl group, and a fluoroalkyl group having a carbon number of 1 or more and 10 or less,
b is a number of 0 or more and less than 4, c is a number more than 0 and 4 or less, and b+c=3 or 4,
in the general formula (1), R² is a group represented by a following general formula (1a), 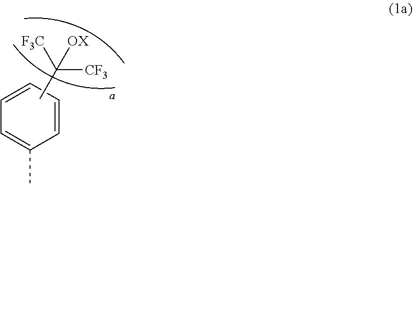
in the general formula (1a), X is a hydrogen atom or an acid-labile group,
a is a number of 1 to 5, and a broken line represents a bond,
each R³ is independently selected from a group consisting of a hydrogen atom, an alkyl group having a carbon number of 1 or more and 5 or less, a phenyl group, and a fluoroalkyl group having a carbon number of 1 or more and 10 or less, and each R⁴ is independently a hydrogen atom or an alkyl group having a carbon number of 1 or more and 5 or less,
d is a number of 1 or more and 3 or less, e is a number of 0 or more and 2 or less, f is a number of 0 or more and less than 3, g is a number more than 0 and 3 or less, and d+e+f+g=4.

22. The method for producing a polymer according to claim 21 further comprising:
adding a chelator to the metal compound represented by the general formula (1-2) during the hydrolysis and polycondensation or before the hydrolysis and polycondensation.

23. A method for producing a resin composition comprising:
performing at least one operation selected from a group consisting of a dilution, a condensation, an extraction, a water washing, an ion exchange resin purification and a filtration with respect to the polymer obtained by the method for producing the polymer according to claim 21.
